(19) United States
(12) Patent Application Publication
(10) Pub. No.: US 2026/0237338 A1
(43) Pub. Date: Aug. 13, 2026

(54) Gate Driver, Display Device Including The Gate Driver, And Electronic Device Including The Display Device

(71) Applicants: Samsung Display Co., Ltd., Yongin-si (KR); Konkuk University Industrial Cooperation Corp., Seoul (KR)

(72) Inventors: Heerim Song, Yongin-si (KR); HyeongMin Kim, Seoul (KR); Nackhyeon Keum, Yongin-si (KR); KeeChan Park, Seoul (KR); Kyung-Hoon Kim, Yongin-si (KR); Sanghun Kim, Yongin-si (KR)

(73) Assignees: Samsung Display Co., Ltd., Yongin-si (KR); Konkuk University Industrial Cooperation Corp., Yongin-si (KR)

(21) Appl. No.: 19/447,136

(22) Filed: Jan. 13, 2026

(30) Foreign Application Priority Data
Feb. 7, 2025 (KR) 10-2025-0016128

(51) Int. Cl. G09G 3/20

(52) U.S. Cl. CPC G09G 3/2092; G09G 2310/0267; G09G 2330/021

(57) ABSTRACT

The disclosure provides a gate driver that includes a plurality of stages and is driven based on a high gate voltage and a low gate voltage. In one aspect, the disclosure provides a display device or an electronic device that comprises the gate driver. In one aspect, each stage comprises an input circuit configured to provide an input signal to a first node, a first inverting circuit configured to invert a voltage of the first node and to provide an inverted voltage of the first node to a control node, a second inverting circuit configured to invert a voltage of a gate output node from which a gate signal is output and to provide the inverted voltage to a second node, and a third inverting circuit configured to invert and provide a voltage of the control node to the gate output node.

### CROSS-REFERENCE TO RELATED APPLICATION

This application claims priority under 35 USC § 119 to and the benefit of Korean Patent Application No. 10-2025-0016128, filed on Feb. 7, 2025, the disclosure of which is incorporated by reference herein in its entirety.

### TECHNICAL FIELD

The present disclosure relates to a gate driver, a display device including the gate driver, and an electronic device including the display device. More particularly, the present disclosure relates to a gate driver with improved power consumption, a display device that includes such a gate driver, and an electronic device that includes such a display device.

### BACKGROUND

A display device includes a display panel and a display panel driver. The display panel includes gate lines, data lines, emission lines, and pixels. The display panel driver includes a gate driver for providing a gate signal to the gate lines, a data driver for providing a data voltage to the data lines, an emission driver for providing an emission signal to the emission lines, and a driving controller for controlling the gate driver, the data driver, and the emission driver.

The gate driver may include a plurality of stages, and the stages may sequentially provide the gate signal to the pixels in units of rows. The gate signal may be generated by a gate output circuit included in each of the stages. When the gate output circuit is composed of p-channel Metal-Oxide Semiconductor (PMOS) transistors, the gate output circuit should sufficiently turn on the PMOS transistors to stably output the gate signal, and for this purpose, a number of transistors constituting each of the stages may be large. When the number of transistors constituting each of the stages is large, an area occupied by the gate driver and power consumption of the gate driver may be large.

Accordingly, there is a need for display devices and electronic devices with improved power consumption.

### BRIEF SUMMARY

The disclosure is intended to address various problems including the above-mentioned problems and aims to provide gate drivers with improved power consumption and increased reliability. The present disclosure also provides a display device that includes the contemplated gate driver, and a display device or an electronic device that includes the contemplated display device. However, these tasks are just examples, and the scope of the disclosure is not limited thereby.

Additional aspects will be set forth in part in the description which follows and, in part, will be apparent from the description, or may be learned by practice of the presented embodiments of the disclosure.

In some embodiments, a gate driver with a reduced area and reduced power consumption is disclosed.

In some embodiment, a display device includes the gate driver.

In some embodiments, an electronic device includes the display device.

In some embodiments, the gate driver comprises a plurality of stages and is driven based on a high gate voltage and a low gate voltage. Each stage of the plurality of stages comprises an input circuit configured to provide an input signal to a first node in response to a first clock signal, a first inverting circuit configured to invert a voltage of the first node and to provide an inverted voltage of the first node to a control node, a second inverting circuit configured to invert a voltage of a gate output node from which a gate signal is output and to provide an inverted voltage of the gate output node to a second node, and a third inverting circuit configured to invert a voltage of the control node and to provide an inverted voltage of the control node to the gate output node.

In some embodiments, the input circuit comprises a first transistor including a gate electrode receiving the first clock signal, a first electrode receiving the input signal, and a second electrode connected to the first node.

In some embodiments, the first transistor comprises a PMOS transistor.

In some embodiments, the first inverting circuit comprises: a second transistor including a gate electrode connected to the first node, a first electrode receiving the high gate voltage, and a second electrode connected to the control node; and a third transistor including a gate electrode connected to the first node, a first electrode receiving the low gate voltage, and a second electrode connected to the control node.

In some embodiments, the second transistor comprises a PMOS transistor, the third transistor comprises an NMOS transistor, and the second transistor and the third transistor form a CMOS transistor.

In some embodiments, the second inverting circuit comprises: a fourth transistor including a gate electrode connected to the gate output node, a first electrode receiving the high gate voltage, and a second electrode connected to the second node; and a fifth transistor including a gate electrode connected to the gate output node, a first electrode connected to the control node, and a second electrode connected to the second node.

In some embodiments, the fourth transistor comprises a PMOS transistor, the fifth transistor comprises an NMOS transistor, and the fourth transistor and the fifth transistor form a CMOS transistor.

In some embodiments, the third inverting circuit comprises: a sixth transistor including a gate electrode connected to the control node, a first electrode receiving the high gate voltage, and a second electrode connected to the gate output node; and a seventh transistor including a gate electrode connected to the control node, a first electrode receiving the low gate voltage, and a second electrode connected to the gate output node.

In some embodiments, the sixth transistor comprises a PMOS transistor, the seventh transistor comprises an NMOS transistor, and the sixth transistor and the seventh transistor form a CMOS transistor.

In some embodiments, the control node comprises a first control node and a second control node, and each stage of the plurality of stages further comprises: an eighth transistor including a gate electrode receiving the low gate voltage, a first electrode connected to the first control node, and a second electrode connected to the second control node.

In some embodiments, each state of the plurality of stages further comprises: a first capacitor including a first electrode connected to the first node and a second electrode connected to the gate output node.

In some embodiments, each state of the plurality of stages further comprises: a second capacitor including a first electrode connected to the second node and a second electrode connected to the control node.

In some embodiments, the first inverting circuit comprises: a second transistor including a gate electrode connected to the first node, a first electrode receiving a second clock signal, and a second electrode connected to the control node; and a third transistor including a gate electrode connected to the first node, a first electrode receiving the low gate voltage, and a second electrode connected to the control node.

In some embodiments, the second inverting circuit comprises: a fourth transistor including a gate electrode connected to the gate output node, a first electrode receiving the second clock signal, and a second electrode connected to the second node; and a fifth transistor including a gate electrode connected to the gate output node, a first electrode connected to the control node, and a second electrode connected to the second node.

In some embodiments, the third inverting circuit comprises: a sixth transistor including a gate electrode, a first electrode receiving the high gate voltage, and a second electrode connected to the gate output node; and a seventh transistor including a gate electrode connected to the control node, a first electrode receiving the low gate voltage, and a second electrode connected to the gate output node.

In some embodiments, the control node comprises a first control node and a second control node, and each stage of the plurality of stages further comprises: an eighth transistor including a gate electrode receiving the low gate voltage, a first electrode connected to the first control node, and a second electrode connected to the second control node.

In some embodiments, each stage of the plurality of stages further comprises: a first capacitor including a first electrode connected to the first node and a second electrode connected to the gate output node; and a second capacitor including a first electrode connected to the second node and a second electrode connected to the control node.

In some embodiments, each stage of the plurality of stages further comprises: a ninth transistor including a gate electrode receiving the first clock signal, a first electrode connected to the control node, and a second electrode connected to the gate electrode of the sixth transistor.

In some embodiments, the display device comprises: a display panel including a plurality of pixels; and a gate driver configured to provide a gate signal to the plurality of pixels and driven based on a high gate voltage and a low gate voltage. The gate driver comprises a plurality of stages. Each stage of the plurality of stages comprises an input circuit configured to provide an input signal to a first node in response to a first clock signal, a first inverting circuit configured to invert a voltage of the first node and to provide an inverted voltage of the first node to a control node, a second inverting circuit configured to invert a voltage of a gate output node from which the gate signal is output and to provide an inverted voltage of the gate output node to a second node, and a third inverting circuit configured to invert a voltage of the control node and to provide an inverted voltage of the control node to the gate output node.

In some embodiments, the electronic device comprises: a display panel including a plurality of pixels; a gate driver configured to provide a gate signal to the plurality of pixels and driven based on a high gate voltage and a low gate voltage; and a power supply configured to provide the high gate voltage and the low gate voltage to the gate driver. The gate driver comprises a plurality of stages. Each stage of the plurality of stages comprises an input circuit configured to provide an input signal to a first node in response to a first clock signal, a first inverting circuit configured to invert a voltage of the first node and to provide an inverted voltage of the first node to a control node, a second inverting circuit configured to invert a voltage of a gate output node from which the gate signal is output and to provide an inverted voltage of the gate output node to a second node, and a third inverting circuit configured to invert a voltage of the control node and to provide an inverted voltage of the control node to the gate output node.

Accordingly, in some embodiments of the disclosure, the gate driver, the display device, and the electronic device comprise fewer components, such as transistors and capacitors used in gate drivers. In some embodiments, the components of the gate driver form a CMOS transistor. Accordingly, an area occupied by the gate driver and a power consumption associated with the gate driver may be reduced. In addition, the gate driver may boost a voltage level of an internal node using a capacitor to lower the voltage of the internal node below a low gate voltage, thereby making it possible for the gate driver to stably output a gate signal. That is, the reliability of the gate driver may increase.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram showing a display device according to an embodiment of the present disclosure;

FIG. 2 is a block diagram showing an example of a gate driver according to an embodiment of the present disclosure;

FIG. 3 is a timing diagram showing a gate start signal, a first clock signal, a second clock signal, and gate signals of FIG. 2;

FIG. 4 is a circuit diagram showing an example of a stage included in a gate driver of FIG. 2;

FIG. 5 is a timing diagram showing an example of an operation of a stage of FIG. 4;

FIG. 6 is a circuit diagram showing an example of an operation of a stage of FIG. 4 in a first duration of FIG. 5;

FIG. 7 is a circuit diagram showing an example of an operation of a stage of FIG. 4 in a second duration of FIG. 5;

FIG. 8 is a circuit diagram showing an example of an operation of a stage of FIG. 4 in a third duration of FIG. 5;

FIG. 9 is a block diagram showing an example of a gate driver according to an embodiment of the present disclosure;

FIG. 10 is a timing diagram showing a gate start signal, a first clock signal, a second clock signal, and gate signals of FIG. 2;

FIG. 11 is a circuit diagram showing an example of a stage included in a gate driver of FIG. 9;

FIG. 12 is a timing diagram showing an example of an operation of a stage of FIG. 11;

FIG. 13 is a circuit diagram showing an example of an operation of a stage of FIG. 11 in a first duration of FIG. 12;

FIG. 14 is a circuit diagram showing an example of an operation of a stage of FIG. 11 in a second duration of FIG. 12;

FIG. 15 is a circuit diagram showing an example of an operation of a stage of FIG. 11 in a third duration of FIG. 12;

FIG. 16 is a graph showing a power consumption of a gate driver of FIG. 4;

FIG. 17 is a block diagram showing an electronic device; and

FIG. 18 is a diagram showing an embodiment in which an electronic device of FIG. 17 is implemented as a smartphone of the present disclosure.

### DETAILED DESCRIPTION

While specific embodiments are shown in the drawings and described in detail herein below, the present disclosure may be modified in a variety of ways and realized in many different forms. Accordingly, it will be appreciated that the present disclosure is not limited to the specific disclosed forms, and should be construed to include all modifications, equivalents, or replacements included within the spirit and scope of the present disclosure.

Hereinafter, embodiments of the present disclosure will be described in more detail with reference to the accompanying drawings. When describing with reference to the drawings, identical or corresponding components are given the same drawing reference numerals and redundant descriptions thereof are omitted.

In the examples below, the terms first, second, etc. are not used in a limiting sense but are used for the purpose of distinguishing one component from another. As such, in the present disclosure, it will be understood that when a first element (or area, layer, or portion) is referred to as being "on", "connected to" or "coupled to" a second element or layer, the first element can be directly on, connected or coupled to the second element or layer or intervening elements or layers may be present and disposed in between the first and second elements.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

In the examples below, singular expressions include plural expressions unless the context clearly indicates otherwise.

In the drawings, sizes of components may be exaggerated or reduced for convenience of explanation. For example, a size and thickness of each component shown in the drawing are arbitrarily shown for convenience of explanation, and thus the present implementation of the teachings of the present disclosure are not necessarily limited to what is shown.

In some embodiments, where the implementation is otherwise feasible, specific process sequences may be performed in a different order than described. For example, two processes described sequentially may be performed substantially simultaneously, or may proceed in the reverse order from that described.

In this application, “A and/or B” refers to either A, B, or both A and B, and “at least one of A and B” indicates the case where it is A, or B, or both A and B.

In some aspects, an electronic device according to an embodiment includes the display device described above, and may further include a module or device having additional functions in addition to the display device.

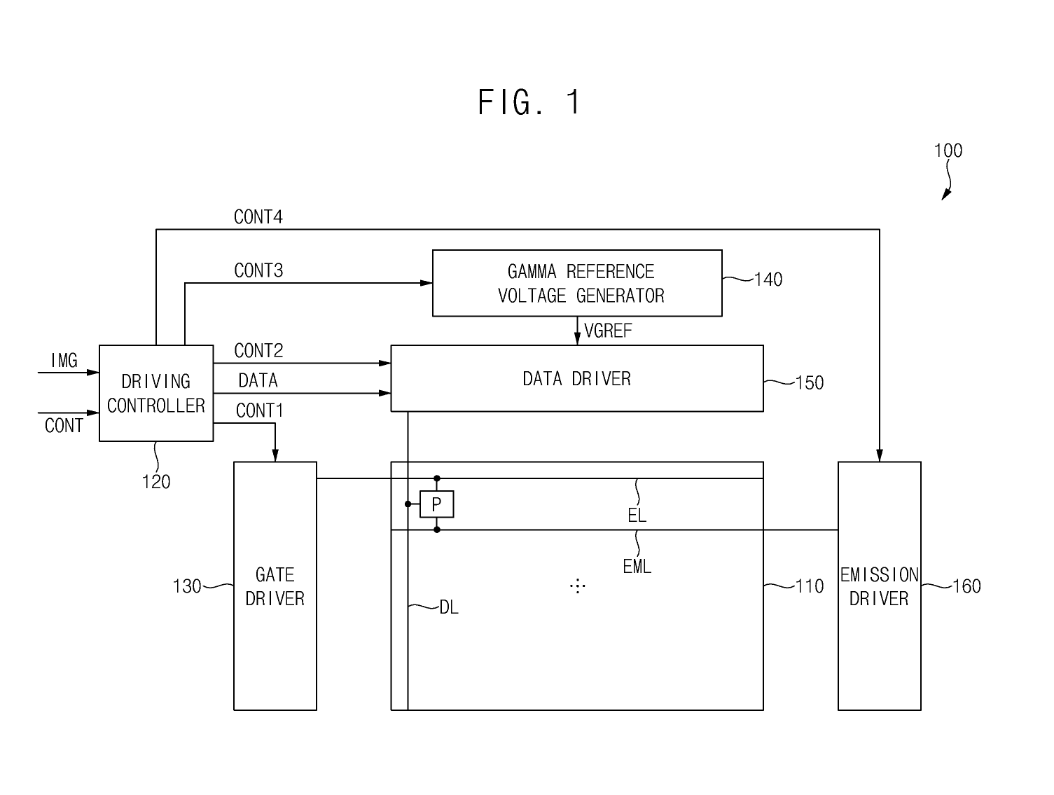

FIG. 1 is a block diagram showing a display device 100 according to an embodiment of the present disclosure.

Referring to FIG. 1, the display device 100 may include a display panel 110 and a display panel driver. The display panel driver may include a driving controller 120, a gate driver 130, a gamma reference voltage generator 140, a data driver 150, and an emission driver 160.

The display panel 110 may include a display area for displaying an image and a peripheral area disposed adjacent to the display area.

The display panel 110 may include gate lines GL, data lines DL, emission lines EML, and pixels PX electrically connected to the gate lines GL, the data lines DL, and the emission lines EML, respectively. The gate lines GL may extend in a first direction, the data lines DL may extend in a second direction crossing the first direction, and the emission lines EML may extend in the first direction.

The driving controller 120 may receive input image data IMG and an input control signal CONT from an external device (not shown). In some aspects, the input image data IMG may include red image data, green image data, and blue image data. In some aspects, the input image data IMG may include white image data. In some aspects, the input image data IMG may include magenta image data, yellow image data, and cyan image data. In some aspects, input control signal CONT may include a master clock signal and a data enable signal. In some aspects, the input control signal CONT may further include a vertical synchronization signal and a horizontal synchronization signal.

The driving controller 120 may generate a first control signal CONT1, a second control signal CONT2, a third control signal CONT3, a fourth control signal CONT4, and a data signal DATA based on the input image data IMG and the input control signal CONT.

The driving controller 120 may generate the first control signal CONT1 for controlling an operation of the gate driver 130 based on the input control signal CONT,and output the first control signal CONT1 to the gate driver 130. The first control signal CONT1 may include a vertical start signal and a gate clock signal.

The driving controller 120 may generate the second control signal CONT2 for controlling an operation of the data driver 150 based on the input control signal CONT, and output the second control signal CONT2 to the data driver 150. The second control signal CONT2 may include a horizontal start signal and a load signal.

The driving controller 120 may generate the data signal DATA based on the input image data IMG. The driving controller 120 may output the data signal DATA to the data driver 150.

The driving controller 120 may generate the third control signal CONT3 for controlling an operation of the gamma reference voltage generator 140 based on the input control signal CONT, and output the third control signal CONT3 to the gamma reference voltage generator 140.

The driving controller 120 may generate the fourth control signal CONT4 for controlling an operation of the emission driver 160 based on the input control signal CONT, and output the fourth control signal CONT4 to the emission driver 160.

The gate driver 130 may generate gate signals for driving the gate lines GL in response to the first control signal CONT1 received from the driving controller 120. The gate driver 130 may output the gate signals to the gate lines GL.

The gamma reference voltage generator 140 may generate a gamma reference voltage VGREF in response to the third control signal CONT3 received from the driving controller 120. The gamma reference voltage generator 140 may provide the gamma reference voltage VGREF to the data driver 150. The gamma reference voltage VGREF may have a value corresponding to each data signal DATA.

For example, the gamma reference voltage generator 140 may be disposed within the driving controller 120 or may be disposed within the data driver 150.

The data driver 150 may receive the second control signal CONT2 and the data signal DATA from the driving controller 120, and receive the gamma reference voltage VGREF from the gamma reference voltage generator 140. The data driver 150 may convert the data signal DATA into a data voltage having an analog type using the gamma reference voltage VGREF. The data driver 150 may output the data voltage to the data line DL.

The emission driver 160 may generate emission signals for driving the emission lines EML in response to the fourth control signal CONT4 received from the driving controller 120. The emission driver 160 may output the emission signals to the emission lines EML.

In FIG. 1, for a convenience of an explanation, the gate driver 130 may be disposed on a first side of the display panel 110 and the emission driver 160 may be disposed on a second side of the display panel 110. Although shown, the present disclosure is not limited thereto. For example, both the gate driver 130 and the emission driver 160 may be disposed

on the first side of the display panel 110. For example, both the gate driver 130 and the emission driver 160 may be disposed on both sides of the display panel 110. For example, the gate driver 130 and the emission driver 160 may be formed integrally.

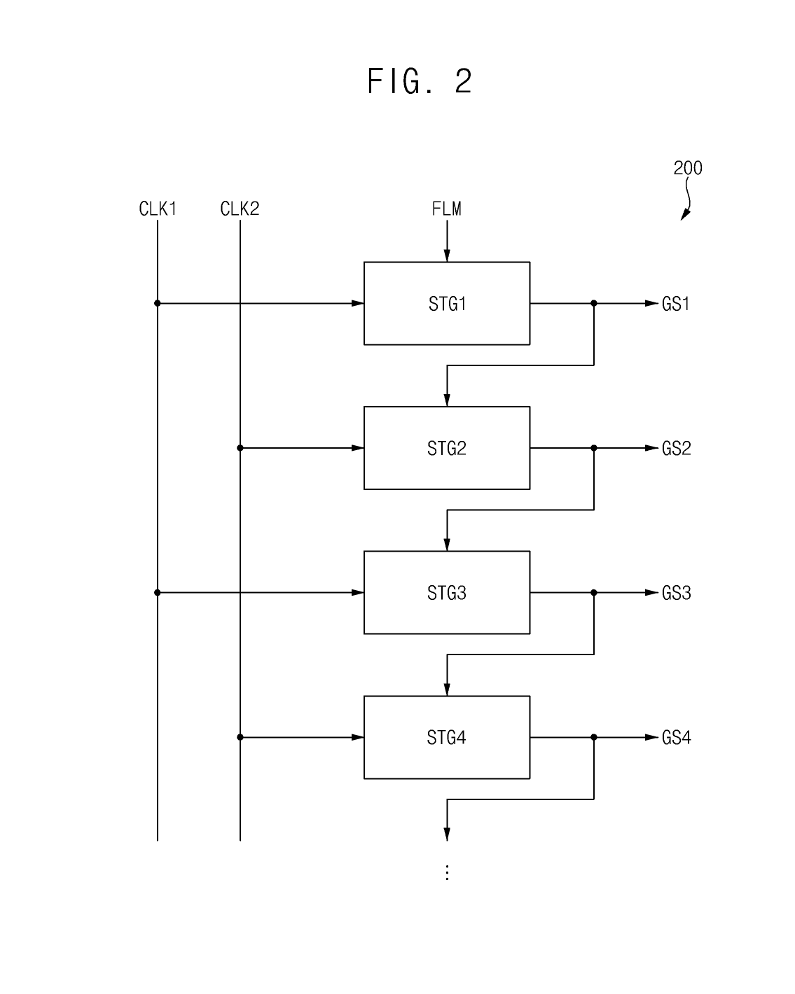

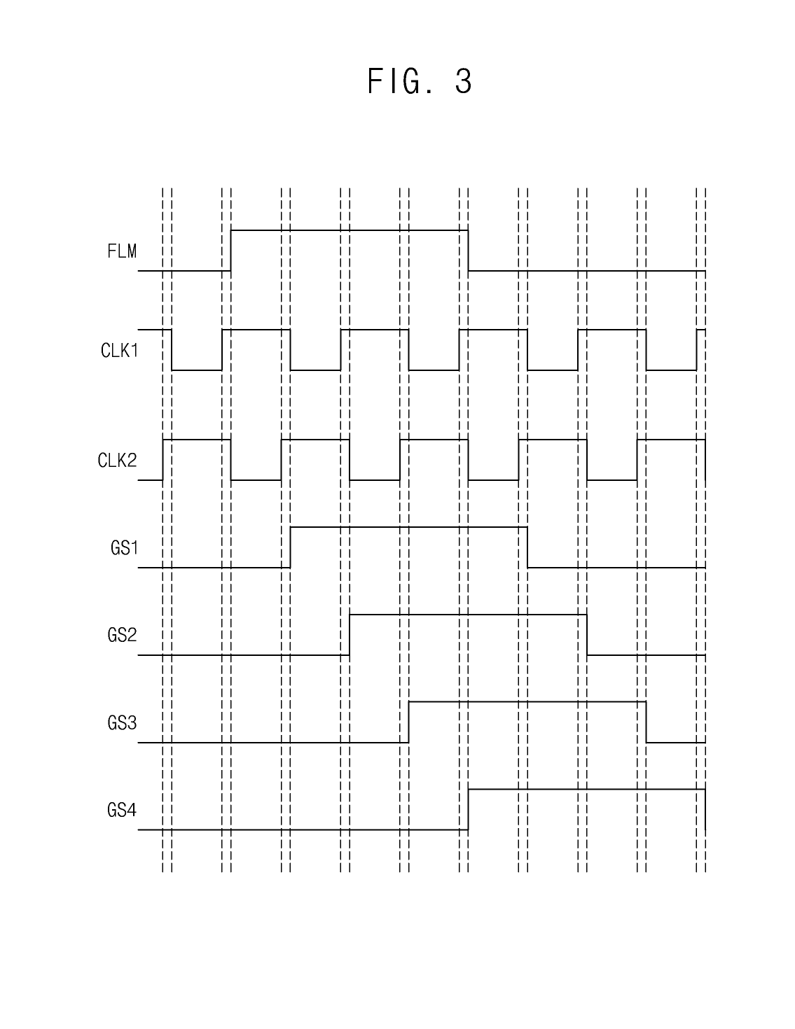

FIG. 2 is a block diagram showing an example 200 of a gate driver 130 according to embodiments of the present disclosure. FIG. 3 is a timing diagram showing a gate start signal FLM, a first clock signal CLK1, a second clock signal CLK2, and gate signals GS1, GS2, GS3, GS4 of FIG. 2.

Referring to FIGS. 1 to 3, a gate driver 200 according to embodiments of the present disclosure may include a plurality of stages STG1, STG2, STG3, STG4, ....

The stages STG1, STG2, STG3, STG4, ... may receive a gate start signal FLM, a first clock signal CLK1, and a second clock signal CLK2. The stages STG1, STG2, STG3, STG4, ... may generate and output gate signals GS1, GS2, GS3, GS4, ...., respectively.

Each stage of the plurality of stages STG1, STG2, STG3, STG4, ... may receive the gate start signal FLM or the gate signals GS1, GS2, GS3, GS4, ... as an input signal. For example, a first stage STG1 may receive the gate start signal FLM as the input signal. For example, subsequent stages STG2, STG3, STG4, ... may receive gate signals GS1, GS2, GS3, GS4, ... of previous stages as the input signal. For example, a second stage STG2 may receive a first gate signal GS1 as the input signal. For example, a third stage STG3 may receive a second gate signal GS2 as the input signal. For example, the fourth stage STG4 may receive a third gate signal GS3 as the input signal.

Each of the stages STG1, STG2, STG3, STG4, ... may alternately receive the first clock signal CLK1 and the second clock signal CLK2, and generate and output the gate signals GS1, GS2, GS3, GS4, ....

For example, the first stage STG1 may receive the first clock signal CLK1, and receive the gate start signal FLM as the input signal in response to the first clock signal CLK1. Therefore, the first stage STG1 may generate and output the first gate signal GS1 in response to the first clock signal CLK1.

For example, the second stage STG2 may receive the second clock signal CLK2, and receive the first gate signal GS1 as the input signal in response to the second clock signal CLK2. Therefore, the second stage STG2 may generate and output the second gate signal GS2 in response to the second clock signal CLK2.

For example, the third stage STG3 may receive the first clock signal CLK1, and receive the second gate signal GS2 as the input signal in response to the first clock signal CLK1. Therefore, the third stage STG3 may generate and output the third gate signal GS3 in response to the first clock signal CLK1.

For example, the fourth stage STG4 may receive the second clock signal CLK2, and receive the third gate signal GS3 as the input signal in response to the second clock signal CLK2. Therefore, the fourth stage STG4 may generate and output the fourth gate signal GS4 in response to the second clock signal CLK2.

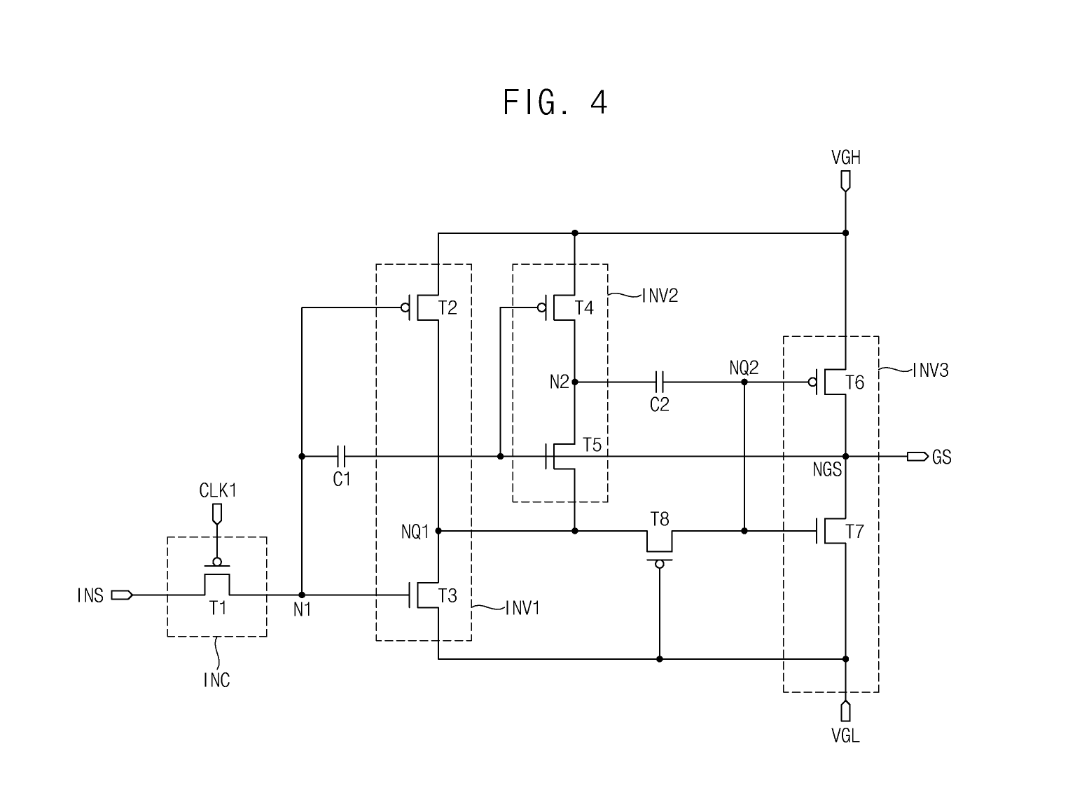

FIG. 4 is a circuit diagram showing an example of a stage included in a gate driver 200 of FIG. 2.

Referring to FIGS. 1 to 4, a gate driver 200 may include a plurality of stages. Each of the stages may include an input circuit INC, a first inverting circuit INV1, a second inverting circuit INV2, and a third inverting circuit INV3.

The input circuit INC may provide an input signal INS to a first node N1 in response to a first clock signal CLK1. The input signal INS may be a gate start signal FLM or a gate signal of a previous stage.

The input circuit INC may include a first transistor T1. In an embodiment, the first transistor T1 may be a PMOS transistor. The first transistor T1 may include a gate electrode receiving the first clock signal CLK1, a first electrode receiving the input signal INS, and a second electrode connected to the first node N1.

The first inverting circuit INV1 may invert a voltage of the first node N1 and provide an inverted voltage of the first node N1 to a control node NQ1, NQ2.

The first inverting circuit INV1 may include a second transistor T2 and a third transistor T3. In an embodiment, the second transistor T2 may be the PMOS transistor, and the third transistor T3 may be an NMOS transistor. In an embodiment, the second transistor T2 and the third transistor T3 may form a CMOS transistor. The second transistor T2 may include a gate electrode connected to the first node N1, a first electrode receiving a high gate voltage VGH, and a second electrode connected to the control node NQ1, NQ2. The third transistor T3 may include a gate electrode connected to the first node N1, a first electrode receiving a low gate voltage VGL, and a second electrode connected to the control node NQ1, NQ2.

The second inverting circuit INV2 may invert the voltage of a gate output node NGS from which a gate signal GS is output and provide the inverted voltage of the gate output node NGS to a second node N2.

The second inverting circuit INV2 may include a fourth transistor T4 and a fifth transistor T5. In an embodiment, the fourth transistor T4 may be the PMOS transistor, and the fifth transistor T5 may be the NMOS transistor. In an embodiment, the fourth transistor T4 and the fifth transistor T5 may form the CMOS transistor. The fourth transistor T4 may include a gate electrode connected to the gate output node NGS, a first electrode receiving the high gate voltage VGH, and a second electrode connected to the second node N2. The fifth transistor T5 may include a gate electrode connected to the gate output node NGS, a first electrode connected to the control node NQ1, NQ2, and a second electrode connected to the second node N2.

The third inverting circuit INV3 may invert a voltage of the control node NQ1, NQ2 and provide an inverted voltage of the control node NQ1, NQ2 to the gate output node NGS.

The third inverting circuit INV3 may include a sixth transistor T6 and a seventh transistor T7. In an embodiment, the sixth transistor T6 may be the PMOS transistor, and the seventh transistor T7 may be the NMOS transistor. In an embodiment, the sixth transistor T6 and the seventh transistor T7 may form the CMOS transistor. The sixth transistor T6 may include a gate electrode connected to the control node NQ1, NQ2, a first electrode receiving the high gate voltage VGH, and a second electrode connected to the gate output node NGS. The seventh transistor T7 may include a gate electrode connected to the control node NQ1, NQ2, a first electrode receiving the low gate voltage VGL, and a second electrode connected to the gate output node NGS.

The control node NQ1, NQ2 may include a first control node NQ1 and a second control node NQ2, and each of the stages may further include an eighth transistor T8. In an embodiment, the eighth transistor T8 may be the PMOS transistor. The eighth transistor T8 may separate the first control node NQ1 and the second control node NQ2 to control a voltage of the first control node NQ1 and a voltage of the second control node NQ2. The eighth transistor T8 may include a gate electrode receiving the low gate voltage VGL, a first electrode connected to the first control node NQ1, and a second electrode connected to the second control node NQ2.

Each of the stages may further include a first capacitor C1. The first capacitor C1 may boost the voltage of the first node N1 based on a changed voltage of the gate output node NGS to lower the voltage of the first node N1 below the low gate voltage VGL. Accordingly, the third transistor T3 may be sufficiently turned off, and a leakage current may be prevented. The first capacitor C1 may include a first electrode connected to the first node N1 and a second electrode connected to the gate output node NGS.

Each of the stages may further include a second capacitor C2. The second capacitor C2 may boost the voltage of the second control node NQ2 based on a changed voltage of the second node N2 to lower the voltage of the second control node NQ2 below the low gate voltage VGL. Accordingly, the seventh transistor T7 may be sufficiently turned off, and the leakage current may be prevented. The second capacitor C2 may include a first electrode connected to the second node N2 and a second electrode connected to the control node NQ1, NQ2.

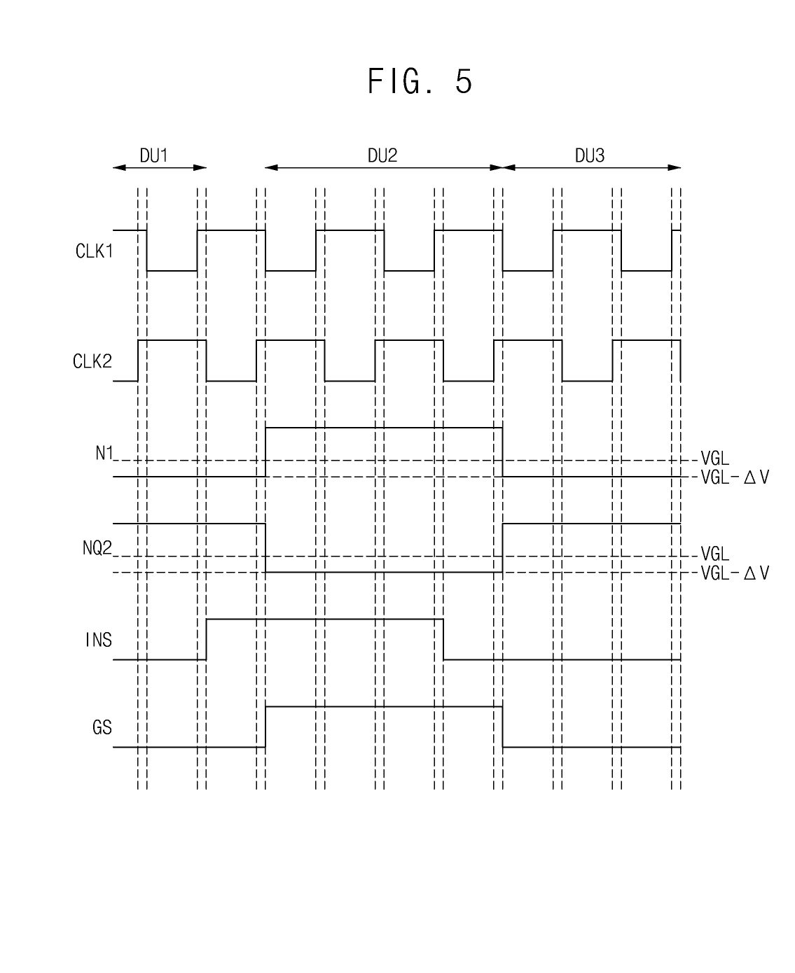

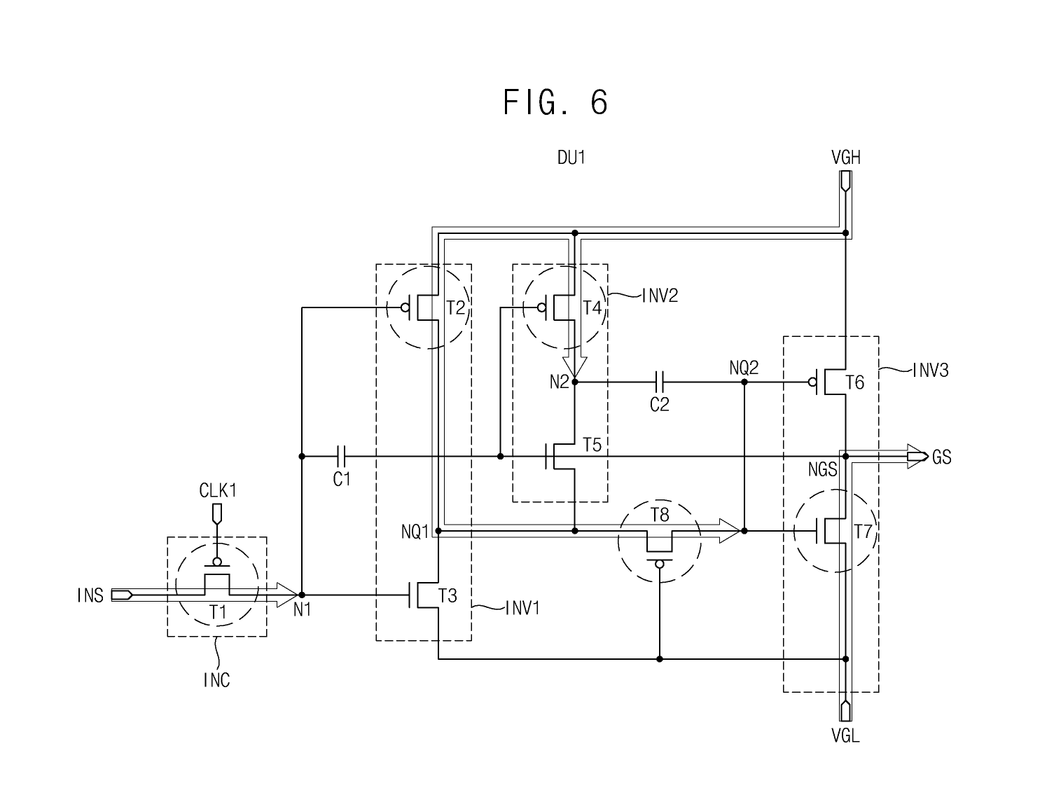

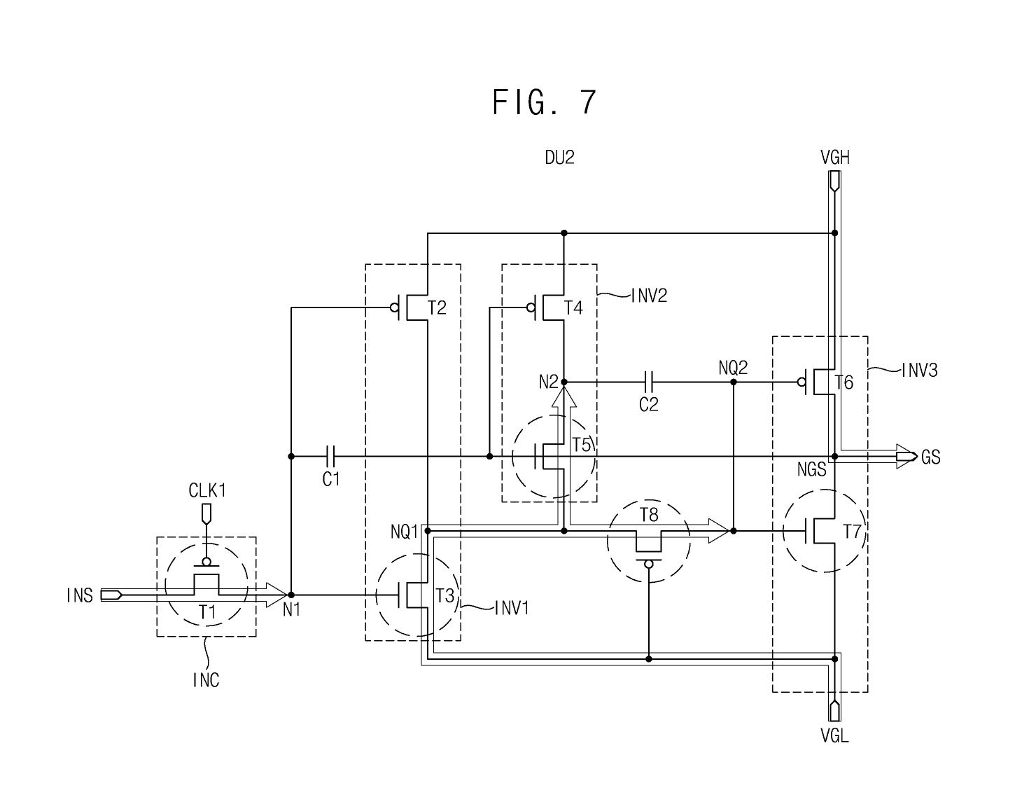

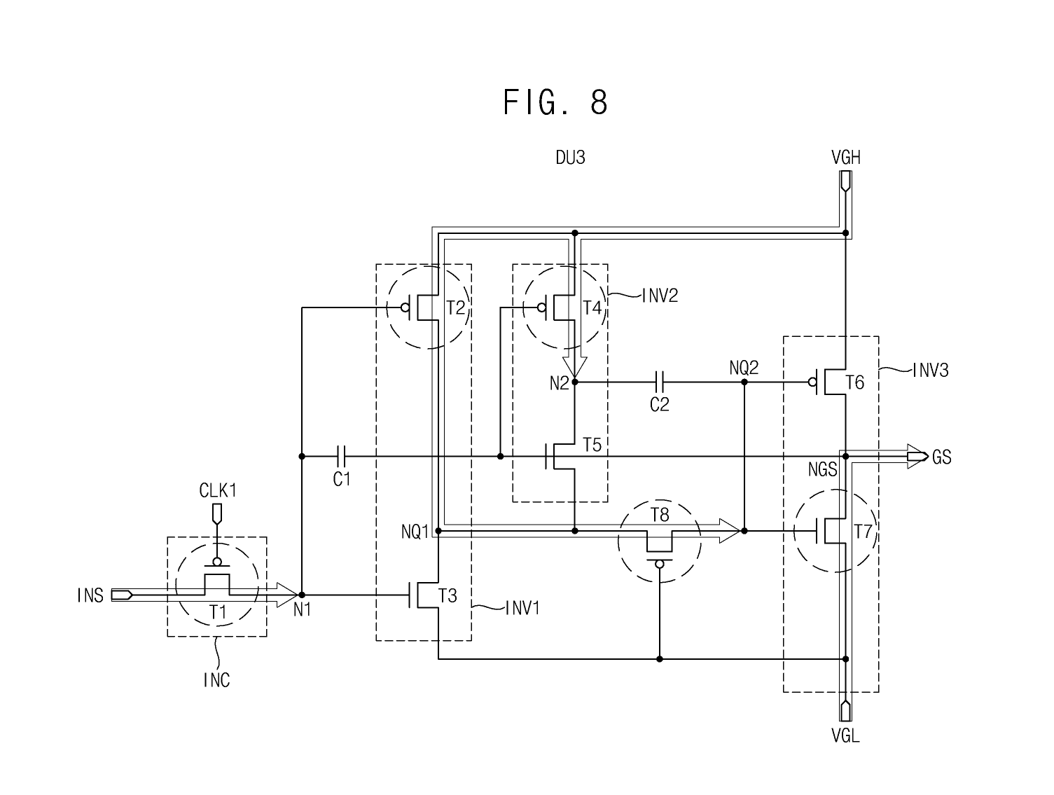

FIG. 5 is a timing diagram showing an example of an operation of a stage of FIG. 4. FIG. 6 is a circuit diagram showing an example of an operation of a stage of FIG. 4 in a first duration DU1 of FIG. 5. FIG. 7 is a circuit diagram showing an example of an operation of a stage of FIG. 4 in a second duration DU2 of FIG. 5. FIG. 8 is a circuit diagram showing an example of an operation of a stage of FIG. 4 in a third duration DU3 of FIG. 5.

Referring to FIGS. 1 to 8, the gate driver 200 may include the stages, and the stages may generate and output the gate signal GS based on the first clock signal CLK1 and the second clock signal CLK2. FIGS. 5 to 8 show a case where the stage generates and outputs the gate signal GS based on the first clock signal CLK1. However, the present disclosure is not limited thereto. FIGS. 5 to 8 may also be applied to a case where the stage generates and outputs the gate signal GS based on the second clock signal CLK2.

Referring to FIGS. 5 and 6, the first transistor T1 may be turned on in response to a first clock signal CLK1 having a low level to provide an input signal INS having the low level to the first node N1. Therefore, the voltage of the first node N1 may have the low level.

The first inverting circuit INV1 may invert the voltage of the first node N1 having the low level and provide an inverted voltage of the first node N1 having a high level to the first control node NQ1. Therefore, the voltage of the first control node NQ1 may have the high level. Specifically, the second transistor T2 may be turned on in response to the voltage of the first node N1 having the low level to provide the high gate voltage VGH to the first control node NQ1. Therefore, the voltage of the first control node NQ1 may have the high level.

The eighth transistor T8 may be turned on in response to the low gate voltage VGL to provide the voltage of the first control node NQ1 having the high level to the second control node NQ2. Therefore, the voltage of the second control node NQ2 may have the high level.

The third inverting circuit INV3 may invert the voltage of the second control node NQ2 having the high level and provide an inverted voltage of the second control node NQ2 having the low level to the gate output node NGS. Therefore, the voltage of the gate output node NGS may have the low level. Specifically, the seventh transistor T7 may be turned on in response to the voltage of the second control node NQ2 having the high level to provide the low gate voltage VGL to the gate output node NGS. Therefore, the voltage of the gate output node NGS may have the low level.

The second inverting circuit INV2 may invert the voltage of the gate output node NGS having the low level and provide the inverted voltage of the gate output node NGS having the high level to the second node N2. Therefore, the voltage of the second node N2 may have the high level. Specifically, the fourth transistor T4 may be turned on in response to the voltage of the gate output node NGS having the low level to provide the high gate voltage VGH to the second node N2. Therefore, the voltage of the second node N2 may have the high level.

Meanwhile, the voltage of the first node N1 may be boosted by the first capacitor C1 to be lowered below the low gate voltage VGL, accordingly the third transistor T3 may be sufficiently turned off, and the leakage current to be prevented.

As the voltage of the gate output node NGS changes from the high level to the low level, the voltage of the gate output node NGS may have the low level. The first capacitor C1 may boost the voltage of the first node N1 by a difference between the high level and the low level, which is the changed voltage of the gate output node NGS, to lower the voltage of the first node N1 below the low gate voltage VGL. Therefore, when the difference between the high level and the low level, which is the changed voltage of the gate output node NGS, is ΔV, the voltage of the first node N1 may be “VGL-ΔV”.

Referring to FIGS. 5 and 7, the first transistor T1 may be turned on in response to the first clock signal CLK1 having the low level to provide the input signal INS having the high level to the first node N1. Therefore, the voltage of the first node N1 may have the high level.

The first inverting circuit INV1 may invert the voltage of the first node N1 having the high level and provide an inverted voltage of the first node N1 having the low level to the first control node NQ1. Therefore, the voltage of the first control node NQ1 may have the low level. Specifically, the third transistor T3 may be turned on in response to the voltage of the first node N1 having the high level to provide the low gate voltage VGL to the first control node NQ1. Therefore, the voltage of the first control node NQ1 may have the low level.

The eighth transistor T8 may be turned on in response to the low gate voltage VGL to provide the voltage of the first control node NQ1 having the low level to the second control node NQ2. Therefore, the voltage of the second control node NQ2 may have the low level.

The third inverting circuit INV3 may invert the voltage of the second control node NQ2 having the low level and provide an inverted voltage of the second control node NQ2 having the high level to the gate output node NGS. Therefore, the voltage of the gate output node NGS may have the high level. Specifically, the sixth transistor T6 may be turned on in response to the voltage of the second control node NQ2 having the low level to provide the high gate voltage VGH to the gate output node NGS. Therefore, the voltage of the gate output node NGS may have the high level.

Meanwhile, the voltage of the second control node NQ2 may be boosted by the second capacitor C2 to be lowered below the low gate voltage VGL, and accordingly the seventh transistor T7 may be sufficiently turned off, and the leakage current may be prevented.

The second inverting circuit INV2 may invert the voltage of the gate output node NGS having the high level and provide an inverted voltage of the gate output node NGS having the low level to the second node N2. Therefore, the voltage of the second node N2 may have the low level. Specifically, the fifth transistor T5 may be turned on in response to the voltage of the gate output node NGS having the high level to provide the voltage of the first control node NQ1 having the low level to the second node N2. Therefore, the voltage of the second node N2 may have the low level.

As the voltage of the second node N2 changes from the high level to the low level, the voltage of the second node N2 may have the low level. The second capacitor C2 may boost the voltage of the second control node NQ2 by a difference between the high level and the low level, which is the changed voltage of the second node N2, to lower the voltage of the second control node NQ2 below the low gate voltage VGL. Therefore, when the difference between the high level and the low level, which is the changed voltages of the second control node NQ2, is ΔV, the voltage of the second control node NQ2 may be “VGL-ΔV”.

A gate-source voltage of the eighth transistor T8 may be “-ΔV”, which is a difference between the low gate voltage VGL and “VGL-ΔV”, which is the voltage of the second control node NQ2, and the eighth transistor T8 may be turned off. Therefore, the eighth transistor T8 may not provide the voltage of the second control node NQ2 to the first control node NQ1. Accordingly, the eighth transistor T8 may separate the first control node NQ1 and the second control node NQ2 to control the voltage of the first control node NQ1 and the voltage of the second control node NQ2.

Referring to FIGS. 5 and 8, the first transistor T1 may be turned on in response to a first clock signal CLK1 having a low level to provide an input signal INS having the low level to the first node N1. Therefore, the voltage of the first node N1 may have the low level.

The first inverting circuit INV1 may invert the voltage of the first node N1 having the low level and provide the inverted voltage of the first node N1 having a high level to the first control node NQ1. Therefore, the voltage of the first control node NQ1 may have the high level. Specifically, the second transistor T2 may be turned on in response to the voltage of the first node N1 having the low level to provide the high gate voltage VGH to the first control node NQ1. Therefore, the voltage of the first control node NQb may have the high level.

The eighth transistor T8 may be turned on in response to the low gate voltage VGL to provide the voltage of the first control node NQ1 having the high level to the second control node NQ2. Therefore, the voltage of the second control node NQ2 may have the high level.

The third inverting circuit INV3 may invert the voltage of the second control node NQ2 having the high level and provide the inverted voltage of the second control node NQ2 having the low level to the gate output node NGS. Therefore, the voltage of the gate output node NGS may have the low level. Specifically, the seventh transistor T7 may be turned on in response to the voltage of the second control node NQ2 having the high level to provide the low gate voltage VGL to the gate output node NGS. Therefore, the voltage of the gate output node NGS may have the low level.

The second inverting circuit INV2 may invert the voltage of the gate output node NGS having the low level and provide the inverted voltage of the gate output node NGS having the high level to the second node N2. Therefore, the voltage of the second node N2 may have the high level. Specifically, the fourth transistor T4 may be turned on in response to the voltage of the gate output node NGS having the low level and provide the high gate voltage VGH to the second node N2. Therefore, the voltage of the second node N2 may have the high level.

Meanwhile, the voltage of the first node N1 may be boosted by the first capacitor C1 and lowered below the low gate voltage VGL, and accordingly the third transistor T3 may be sufficiently turned off, and the leakage current may be prevented.

As the voltage of the gate output node NGS changes from the high level to the low level, the voltage of the gate output node NGS may have the low level. The first capacitor C1 may boost the voltage of the first node N1 by the difference between the high level and the low level, which is the changed voltage of the gate output node NGS to lower the voltage of the first node N1 below the low gate voltage VGL. Therefore, when the difference between the high level and the low level, which is the changed voltage of the gate output node NGS, is ΔV, the voltage of the first node N1 may be “VGL-ΔV.”

As such, a number of components (e.g., a transistor and a capacitor) included in the gate driver 200 may be reduced, and some components may form the CMOS transistor. Accordingly, an area occupied by the gate driver 200 and a power consumption may be reduced. In addition, the gate driver 200 may boost a voltage of an internal node (e.g., the first node N1 and the second control node NQ2) using a capacitor (e.g., the first capacitor C1 and the second capacitor C2) to lower the voltage of the internal node below the low gate voltage VGL, and accordingly the gate driver 200 may stably output the gate signal GS. That is, a reliability of the gate driver 200 may be increased.

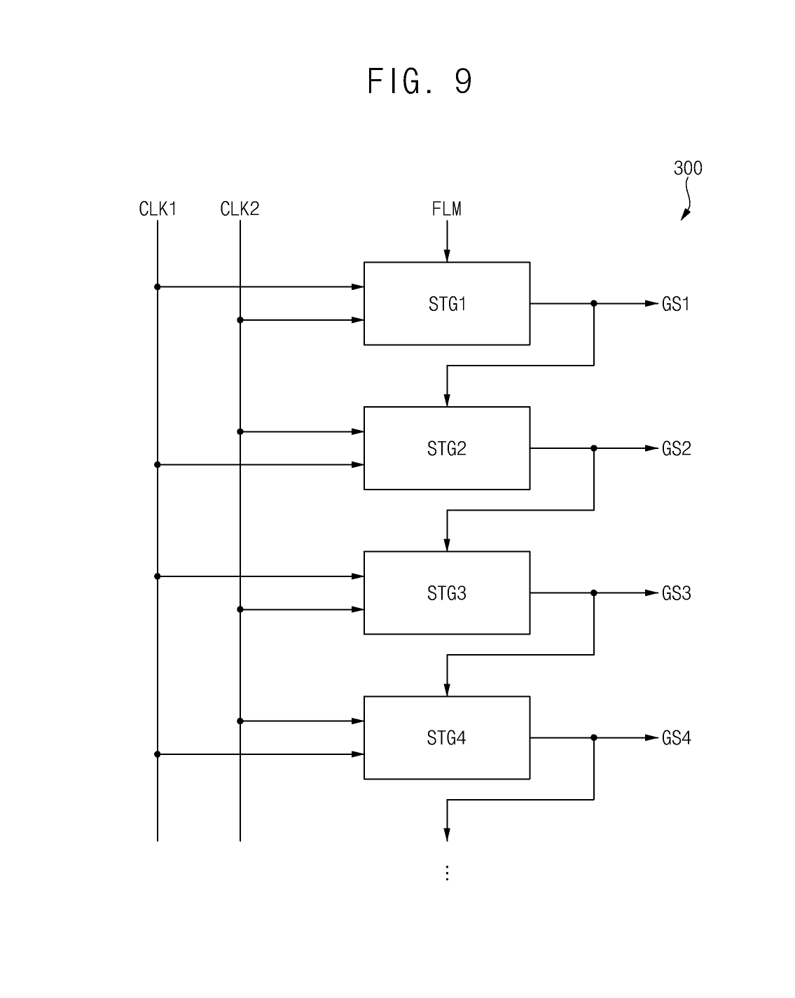

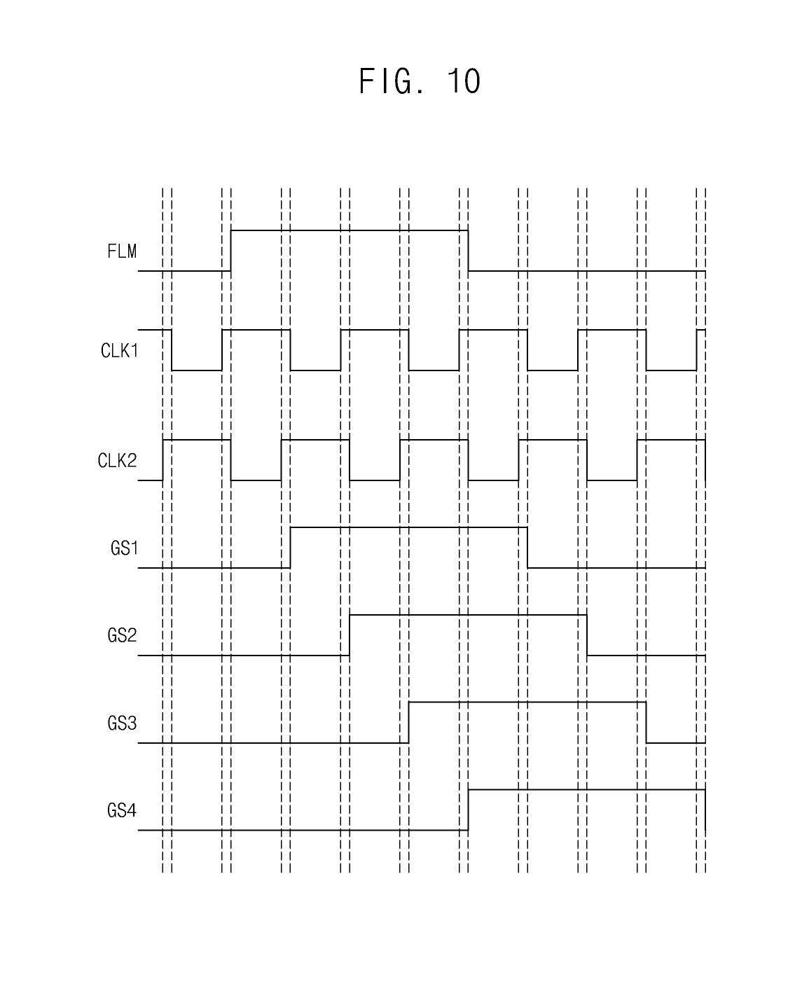

FIG. 9 is a block diagram showing an example 300 of a gate driver 130 according to embodiments of the present disclosure. FIG. 10 is a timing diagram showing a gate start signal FLM, a first clock signal CLK1, a second clock signal CLK2, and gate signals GS1, GS2, GS3, GS4 of FIG. 2.

Referring to FIGS. 1 and FIGS. 9 to 10, a gate driver 300 according to embodiments of the present disclosure may include a plurality of stages STG1, STG2, STG3, STG4, ....

The stages STG1, STG2, STGb, STG4, ... may receive a gate start signal FLM, a first clock signal CLK1, and a second clock signal CLK2. The stages STG1, STG2, STG3, STG4, ... may generate and output one of the gate signals GS1, GS2, GS3, GS4, .... Each stage of the plurality of stages STG1, STG2, STG3, STG4, ... may receive the gate start signal FLM or one of the gate signals GS1, GS2, GS3, GS4, ... as an input signal. For example, a first stage STG1 may receive the gate start signal FLM as the input signal. For example, subsequent stages STG2, STG3, STG4, ... may receive one of gate signals GS1, GS2, GS3, GS4, ... of previous stages as the input signal. For example, a second stage STG2 may receive a first gate signal GS1 as the input signal. For example, a third stage STG3 may receive a second gate signal GS2 as the input signal. For example, a fourth stage STG4 may receive a third gate signal GS3 as the input signal.

Each of the stages STG1, STG2, STG3, STG4, ... may alternately receive the first clock signal CLK1 and the second clock signal CLK2, and generate and output one of the gate signals GS1, GS2, GS3, GS4, ....

For example, the first stage STG1 may receive the first clock signal CLK1, and may receive the gate start signal FLM as the input signal in response to the first clock signal CLK1. The first stage STG1 may receive the second clock signal CLK2, and control a voltage of an internal node of the first stage STG1 in response to the first clock signal CLK1 and the second clock signal CLK2. Therefore, the first stage STG1 may generate and output the first gate signal GS1 in response to the first clock signal CLK1 and the second clock signal CLK2.

For example, the second stage STG2 may receive the second clock signal CLK2 and, receive the first gate signal GS1 as the input signal in response to the second clock signal CLK2. The second stage STG2 may receive the first clock signal CLK1, and control a voltage of an internal node of the second stage STG2 in response to the first clock signal CLK1 and the second clock signal CLK2. Therefore, the second stage STG2 may generate and output the second gate signal GS2 in response to the first clock signal CLK1 and the second clock signal CLK2.

For example, the third stage STG3 may receive the first clock signal CLK1, and receive the second gate signal GS2 as the input signal in response to the first clock signal CLK1. The third stage STG3 may receive the second clock signal CLK2, and control a voltage of an internal node of the third stage STG3 in response to the first clock signal CLK1 and the second clock signal CLK2. Therefore, the third stage STG3 may generate and output the third gate signal GS3 in response to the first clock signal CLK1 and the second clock signal CLK2.

For example, the fourth stage STG4 may receive the second clock signal CLK2, and receive the third gate signal GS3 as the input signal in response to the second clock signal CLK2. The fourth stage STG4 may receive the first clock signal CLK1, and control a voltage of an internal node of the fourth stage STG4 in response to the first clock signal CLK1 and the second clock signal CLK2. Therefore, the fourth stage STG4 may generate and output the fourth gate signal GS4 in response to the first clock signal CLK1 and the second clock signal CLK2.

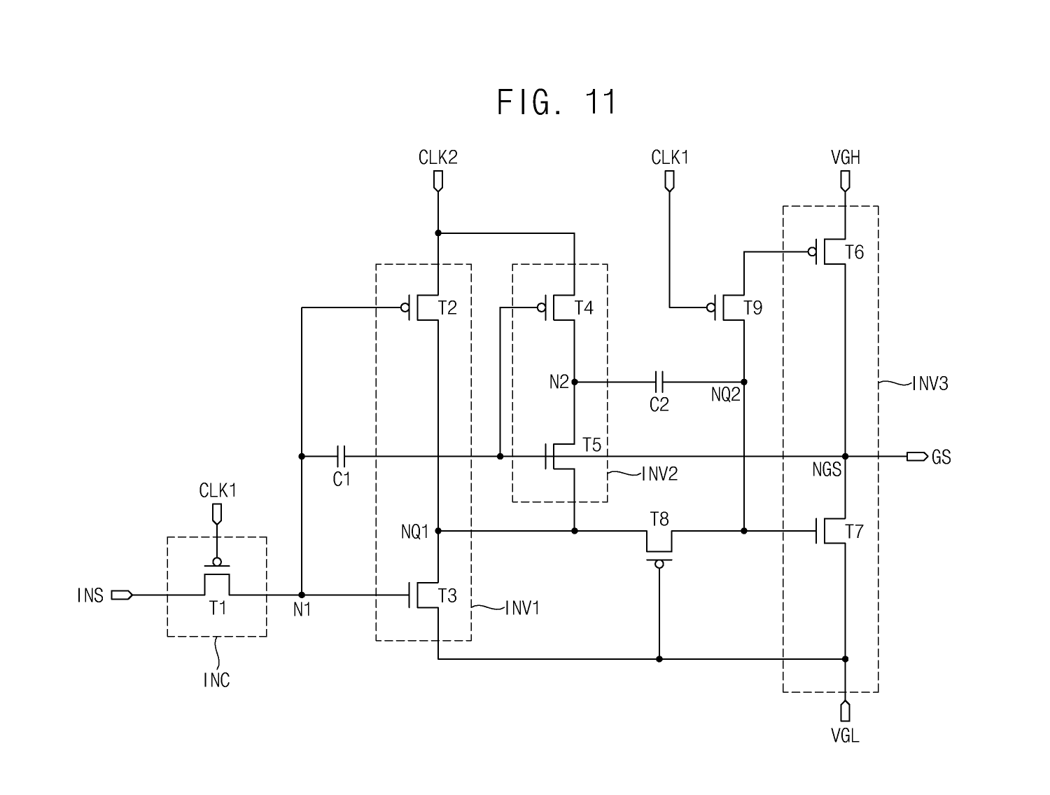

FIG. 11 is a circuit diagram showing an example of a stage included in a gate driver 300 of FIG. 9.

Referring to FIGS. 1 and FIGS. 9 to 11, a gate driver 300 may include a plurality of stages. Each of the stages may include an input circuit INC, a first inverting circuit INV1, a second inverting circuit INV2, and a third inverting circuit INV3.

The input circuit INC may provide an input signal INS to a first node N1 in response to a first clock signal CLK1. The input signal INS may be a gate start signal FLM or a gate signal of a previous stage.

The input circuit INC may include a first transistor T1. In an embodiment, the first transistor T1 may be a PMOS transistor. The first transistor T1 may include a gate electrode receiving the first clock signal CLK1, a first electrode receiving the input signal INS, and a second electrode connected to the first node N1.

The first inverting circuit INV1 may invert a voltage of the first node N1 and provide an inverted voltage of the first node N1 to the control node NQ1, NQ2.

The first inverting circuit INV1 may include a second transistor T2 and a third transistor T3. In an embodiment, the second transistor T2 may be the PMOS transistor, and the third transistor T3 may be an NMOS transistor. In an embodiment, the second transistor T2 and the third transistor T3 may form a CMOS transistor. The second transistor T2 may include a gate electrode connected to the first node N1, a first electrode receiving a second clock signal CLK2, and a second electrode connected to the control node NQ1, NQ2. The third transistor T3 may include a gate electrode connected to the first node N1, a first electrode receiving a low gate voltage VGL, and a second electrode connected to the control node NQ1, NQ2.

The second inverting circuit INV2 may invert a voltage of a gate output node NGS from which a gate signal GS is output and provide an inverted voltage of the gate output node NGS to a second node N2.

The second inverting circuit INV2 may include a fourth transistor T4 and a fifth transistor T5. In an embodiment, the fourth transistor T4 may be the PMOS transistor, and the fifth transistor T5 may be the NMOS transistor. In an embodiment, the fourth transistor T4 and the fifth transistor T5 may form the CMOS transistor. The fourth transistor T4 may include a gate electrode connected to the gate output node NGS, a first electrode receiving the second clock signal CLK2, and a second electrode connected to the second node N2. The fifth transistor T5 may include a gate electrode connected to the gate output node NGS, a first electrode connected to the control node NQ1, NQ2, and a second electrode connected to the second node N2.

The third inverting circuit INV3 may invert a voltage of the control node NQ1, NQ2 and provide an inverted voltage of the control node NQ1, NQ2 to the gate output node NGS.

The third inverting circuit INV3 may include a sixth transistor T6 and a seventh transistor T7. In an embodiment, the sixth transistor T6 may be the PMOS transistor, and the seventh transistor T7 may be the NMOS transistor. In an embodiment, the sixth transistor T6 and the seventh transistor T7 may form the CMOS transistor. The sixth transistor T6 may include a gate electrode, a first electrode receiving a high gate voltage VGH, and a second electrode connected to the gate output node NGS. The seventh transistor T7 may include a gate electrode connected to the control node NQ1, NQ2, a first electrode receiving the low gate voltage VGL, and a second electrode connected to the gate output node NGS.

The control node NQ1, NQ2 may include a first control node NQ1 and a second control node NQ2, and each of the stages may further include an eighth transistor T8. In an embodiment, the eighth transistor T8 may be the PMOS transistor. The eighth transistor T8 may separate the first control node NQ1 and the second control node NQ2 to control a voltage of the first control node NQ1 and a voltage of the second control node NQ2. The eighth transistor T8 may include a gate electrode receiving the low gate voltage VGL, a first electrode connected to the first control node NQ1, and a second electrode connected to the second control node NQ2.

Each of the stages may further include a first capacitor C1. The first capacitor C1 may boost the voltage of the first node N1 based on a changed voltage of the gate output node NGS to lower the voltage of the first node N1 below the low gate voltage VGL. Accordingly, the third transistor T3 may be sufficiently turned off, and a leakage current may be prevented. The first capacitor C1 may include a first electrode connected to the first node N1 and a second electrode connected to the gate output node NGS.

Each of the stages may further include a second capacitor C2. The second capacitor C2 may boost the voltage of the second control node NQ2 based on a changed voltage of the second node N2 to lower the voltage of the second control node NQ2 below the low gate voltage VGL. Accordingly, the seventh transistor T7 may be sufficiently turned off, and the leakage current may be prevented. The second capacitor C2 may include a first electrode connected to the second node N2 and a second electrode connected to the control node NQ1, NQ2.

Each of the stages may further include a ninth transistor T9. In an embodiment, the ninth transistor T9 may be the PMOS transistor. The ninth transistor T9 may include a gate electrode receiving the first clock signal CLK1, a first electrode connected to the control node NQ1, NQ2, and a second electrode connected to the gate electrode of the sixth transistor T6.

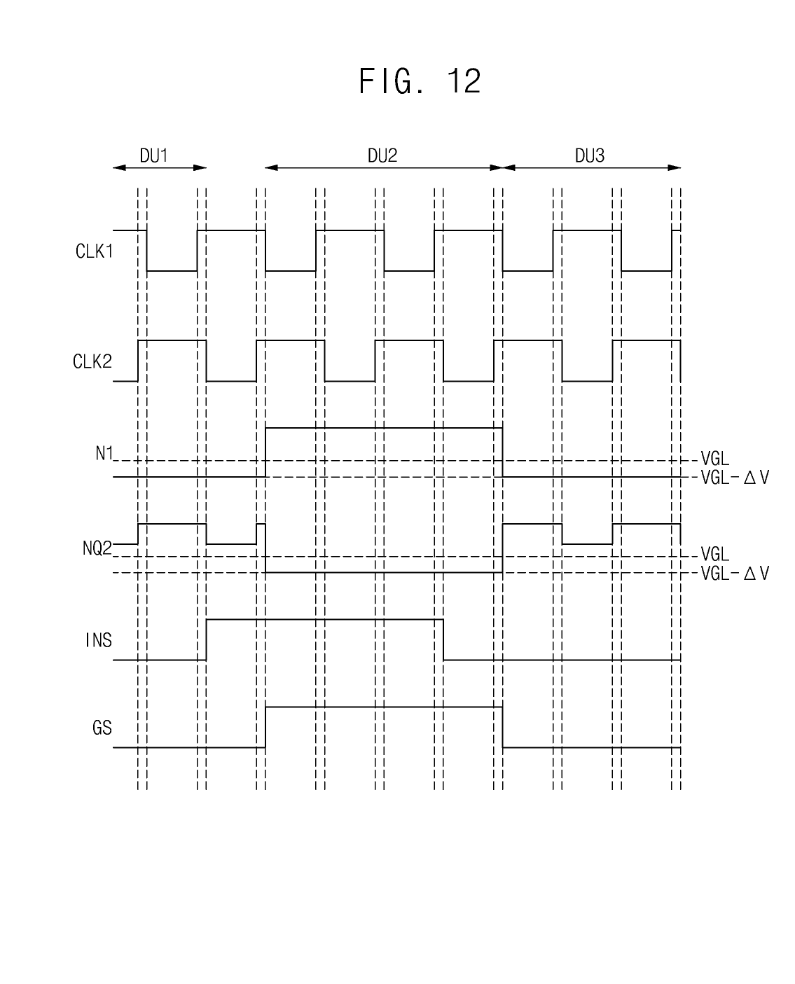

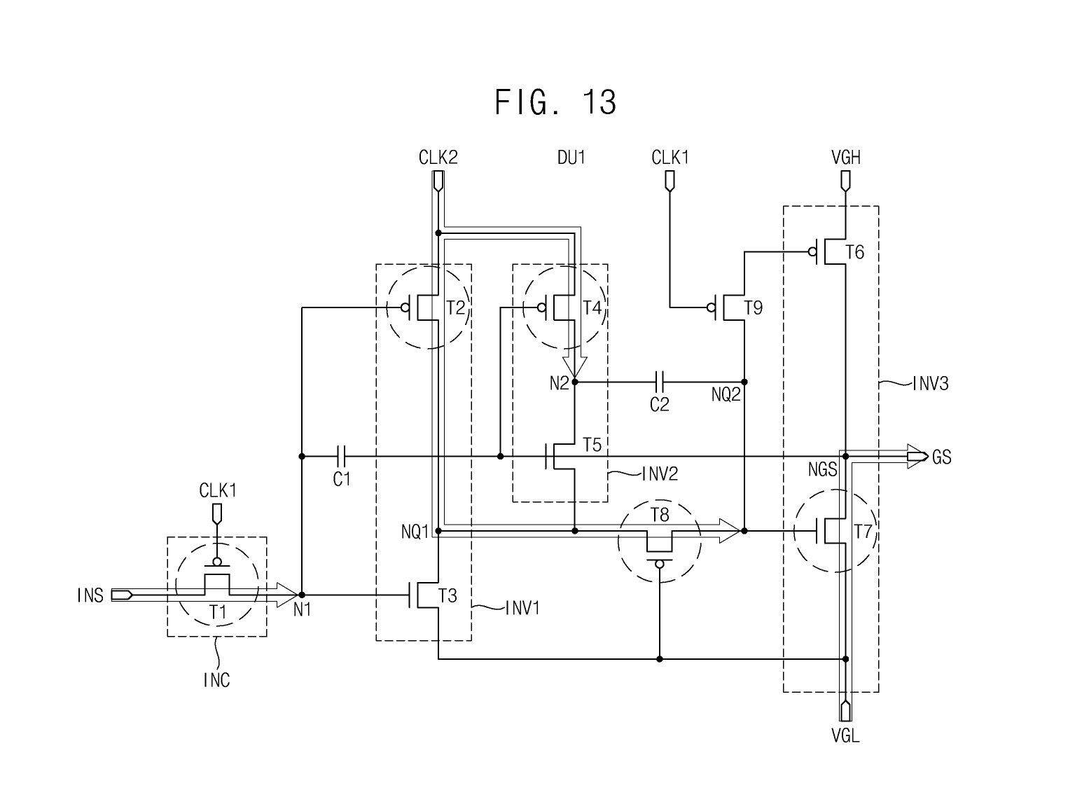

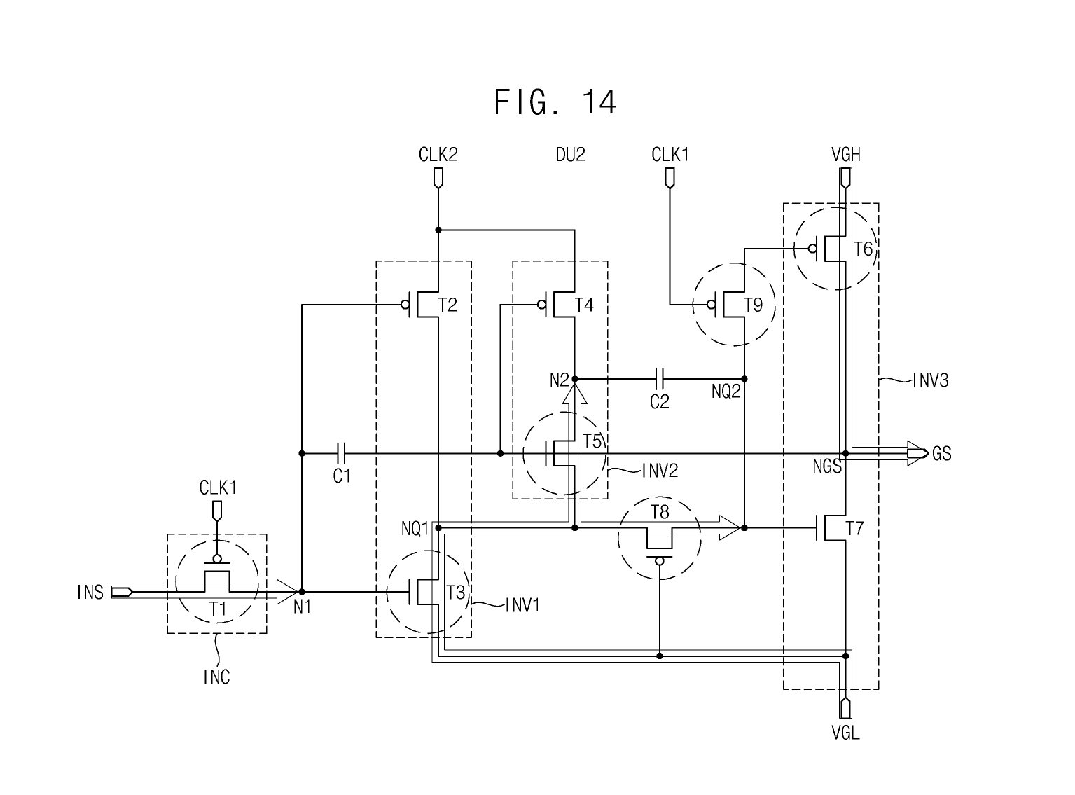

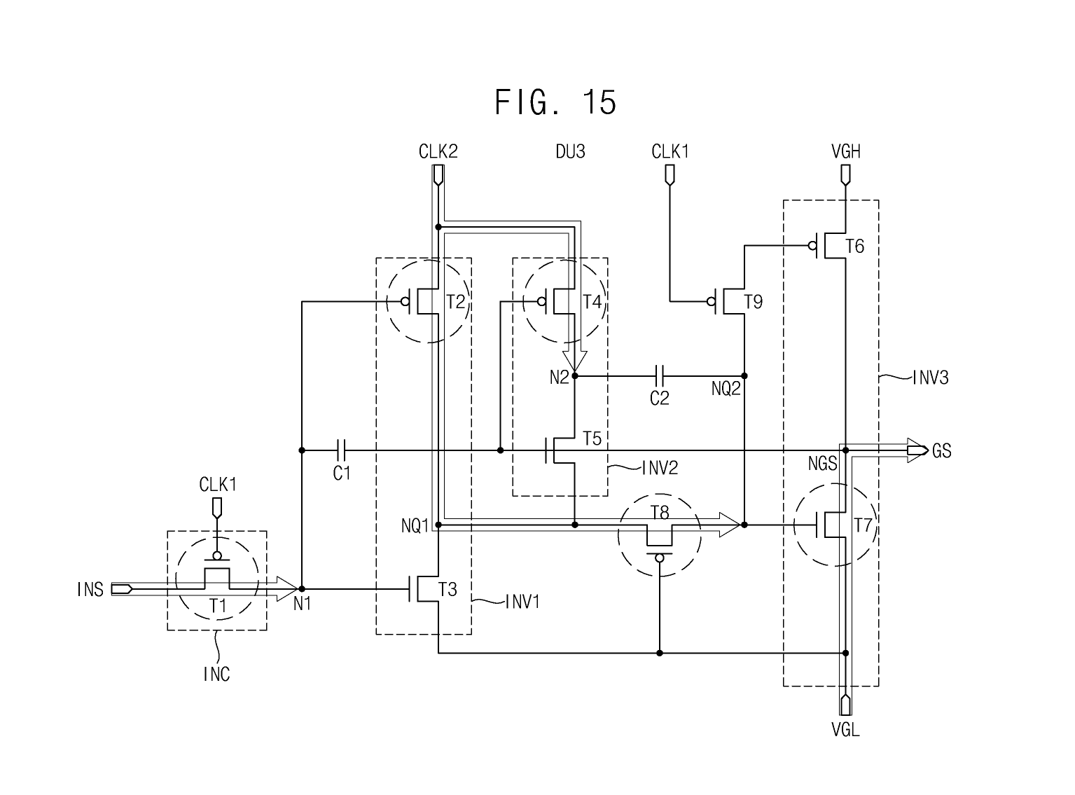

FIG. 12 is a timing diagram showing an example of an operation of a stage of FIG. 11. FIG. 13 is a circuit diagram showing an example of an operation of a stage of FIG. 11 in a first duration DU1 of FIG. 12. FIG. 14 is a circuit diagram showing an example of an operation of a stage of FIG. 11 in a second duration DU2 of FIG. 12. FIG. 15 is a circuit diagram showing an example of an operation of a stage of FIG. 11 in a third duration DU3 of FIG. 12.

Referring to FIGS. 1 and FIGS. 9 to 15, the gate driver 300 may include the stages, and the stages may generate and output the gate signal GS based on the first clock signal CLK1 and the second clock signal CLK2. FIGS. 12 to 15 show a case where the stage receives the input signal INS in response to the first clock signal CLK1 and controls a voltage of an internal node of the stage in response to the first clock signal CLK1 and the second clock signal CLK2. However, the present disclosure is not limited thereto. FIGS. 12 to 15 may also be applied to a case where the stage receives the input signal INS in response to the second clock signal CLK2 and controls a voltage of the internal node of the stage in response to the first clock signal CLK1 and the second clock signal CLK2.

Referring to FIGS. 12 and 13, the first transistor T1 may be turned on in response to a first clock signal CLK1 having a low level to provide an input signal INS having the low level to the first node N1. Therefore, the voltage of the first node N1 may have the low level.

The first inverting circuit INV1 may invert the voltage of the first node N1 having the low level and provide an inverted voltage of the first node N1 having the high level to the first control node NQ1. Therefore, the voltage of the first control node NQ1 may have the high level. Specifically, the second transistor T2 may be turned on in response to the voltage of the first node N1 having the low level and provide the second clock signal CLK2 to the first control node NQ1. Therefore, the voltage of the first control node NQ1 may have the high level. Meanwhile, the second clock signal CLK2 may be toggled. Therefore, the voltage of the first control node NQ1 may be toggled.

The eighth transistor T8 may be turned on in response to the low gate voltage VGL to provide the voltage of the first control node NQ1 having the high level to the second control node NQ2. Therefore, the voltage of the second control node NQ2 may have the high level. The voltage of the second control node NQ2 may be toggled.

The third inverting circuit INV3 may invert the voltage of the second control node NQ2 having the high level and provide an inverted voltage of the second control node NQ2 having the low level to the gate output node NGS. Therefore, the voltage of the gate output node NGS may have the low level. Specifically, the seventh transistor T7 may be turned on in response to the voltage of the second control node NQ2 having the high level to provide the low gate voltage VGL to the gate output node NGS. Therefore, the voltage of the gate output node NGS may have the low level.

The second inverting circuit INV2 may invert the voltage of the gate output node NGS having the low level and provide an inverted voltage of the gate output node NGS having the high level to the second node N2. Therefore, the voltage of the second node N2 may have the high level. Specifically, the fourth transistor T4 may be turned on in response to the voltage of the gate output node NGS having the low level to provide the high gate voltage VGH to the second node N2. Therefore, the voltage of the second node N2 may have the high level.

Meanwhile, the voltage of the first node N1 may be boosted by the first capacitor C1 to be lowered below the low gate voltage VGL, and accordingly the third transistor T3 may be sufficiently turned off, and the leakage current may be prevented.

As the voltage of the gate output node NGS changes from the high level to the low level, the voltage of the gate output node NGS may have the low level. The first capacitor C1 may boost the voltage of the first node N1 by a difference between the high level and the low level, which is the changed voltage of the gate output node NGS, to lower the voltage of the first node N1 below the low gate voltage VGL. Therefore, when the difference between the high level and the low level, which is the changed voltage of the gate output node NGS, is ΔV, the voltage of the first node N1 may be “VGL-ΔV”.

Referring to FIGS. 12 and 14, the first transistor T1 may be turned on in response to the first clock signal CLK1 having the low level to provide the input signal INS having the high level to the first node N1. Therefore, the voltage of the first node N1 may have the high level.

The first inverting circuit INV1 may invert the voltage of the first node N1 having the high level and provide an inverted voltage of the first node N1 having the low level to the first control node NQ1. Therefore, the voltage of the first control node NQ1 may have the low level. Specifically, the third transistor T3 may be turned on in response to the voltage of the first node N1 having the high level to provide the low gate voltage VGL to the first control node NQ1. Therefore, the voltage of the first control node NQ1 may have the low level.

The eighth transistor T8 may be turned on in response to the low gate voltage VGL to provide the voltage of the first control node NQ1 having the low level to the second control node NQ2. Therefore, the voltage of the second control node NQ2 may have the low level.

The third inverting circuit INV3 may invert the voltage of the second control node NQ2 having the low level and provide an inverted voltage of the second control node NQ2 having the high level to the gate output node NGS. Therefore, the voltage of the gate output node NGS may have the high level. Specifically, the ninth transistor T9 may be turned on in response to the first clock signal CLK1 having the low level to provide the voltage of the second control node NQ2 having the low level to the gate electrode of the sixth transistor T6. Therefore, the voltage of the gate electrode of the sixth transistor T6 may have the low level. The sixth transistor T6 may be turned on in response to the voltage of the gate electrode of the sixth transistor T6 having the low level to provide the high gate voltage VGH to the gate output node NGS. Therefore, the voltage of the gate output node NGS may have the high level.

Meanwhile, the voltage of the second control node NQ2 may be boosted by the second capacitor C2 to be lowered below the low gate voltage VGL, and accordingly the seventh transistor T7 may be sufficiently turned off, and the leakage current may be prevented.

The second inverting circuit INV2 may invert the voltage of the gate output node NGS having the high level and provide an inverted voltage of the gate output node NGS having the low level to the second node N2. Therefore, the voltage of the second node N2 may have the low level. Specifically, the fifth transistor T5 may be turned on in response to the voltage of the gate output node NGS having the high level to provide the voltage of the first control node NQ1 having the low level to the second node N2. Therefore, the voltage of the second node N2 may have the low level.

As the voltage of the second node N2 changes from the high level to the low level, the voltage of the second node N2 may have the low level. The second capacitor C2 may boost the voltage of the second control node NQ2 a the difference between the high level and the low level, which is the changed voltage of the second node N2 to lower the voltage of the second control node NQ2 below the low gate voltage VGL. Therefore, when the difference between the high level and the low level, which is the changed voltage of the second control node NQ2, is ΔV, the voltage of the second control node NQ2 may be “VGL-ΔV”.

A gate-source voltage of the eighth transistor T8 may be “-ΔV”, which is a difference between the low gate voltage VGL and “VGL-ΔV”, which is the voltage of the second control node NQ2, and the eighth transistor T8 may be turned off. Therefore, the eighth transistor T8 may not provide the voltage of the second control node NQ2 to the first control node NQ1. Therefore, the eighth transistor T8 may separate the first control node NQ1 and the second control node NQ2 to control the voltage of the first control node NQ1 and the voltage of the second control node NQ2.

Referring to FIGS. 12 and 15, the first transistor T1 may be turned on in response to a first clock signal CLK1 having a low level to provide an input signal INS having the low level to the first node N1. Therefore, the voltage of the first node N1 may have the low level.

The first inverting circuit INV1 may invert the voltage of the first node N1 having the low level and provide the inverted voltage of the first node N1 having the high level to the first control node NQ1. Therefore, the voltage of the first control node NQ1 may have the high level. Specifically, the second transistor T2 may be turned on in response to the voltage of the first node N1 having the low level to provide the second clock signal CLK2 to the first control node NQ1. Therefore, the voltage of the first control node NQ1 may have the high level. Meanwhile, the second clock signal CLK2 may be toggled. Therefore, the voltage of the first control node NQ1 may be toggled.

The eighth transistor T8 may be turned on in response to the low gate voltage VGL to provide the voltage of the first control node NQ1 having the high level to the second control node NQ2. Therefore, the voltage of the second control node NQ2 may have the high level. The voltage of the second control node NQ2 may be toggled.

The third inverting circuit INV3 may invert the voltage of the second control node NQ2 having the high level and provide the inverted voltage of the second control node NQ2 having the low level to the gate output node NGS. Therefore, the voltage of the gate output node NGS may have the low level. Specifically, the seventh transistor T7 may be turned on in response to the voltage of the second control node NQ2 having the high level to provide the low gate voltage VGL to the gate output node NGS. Therefore, the voltage of the gate output node NGS may have the low level.

The second inverting circuit INV2 may invert the voltage of the gate output node NGS having the low level and provide the inverted voltage of the gate output node NGS having the high level to the second node N2. Therefore, the voltage of the second node N2 may have the high level. Specifically, the fourth transistor T4 may be turned on in response to the voltage of the gate output node NGS having the low level to provide the high gate voltage VGH to the second node N2. Therefore, the voltage of the second node N2 may have the high level.

Meanwhile, the voltage of the first node N1 may be boosted by the first capacitor C1 to be lowered below the low gate voltage VGL, and accordingly the third transistor T3 may be sufficiently turned off, and the leakage current may be prevented.

As the voltage of the gate output node NGS changes from the high level to the low level, the voltage of the gate output node NGS may have the low level. The first capacitor C1 may boost the voltage of the first node N1 by the difference between the high level and the low level, which is the changed voltage of the gate output node NGS, to lower the voltage of the first node N1 below the low gate voltage VGL. Therefore, when the difference between the high level and the low level, which is the changed voltage of the gate output node NGS, is ΔV, the voltage of the first node N1 may be “VGL-ΔV”.

As such, the number of components (e.g., a transistor and a capacitor) included in the gate driver 300 may be reduced, and some of the components may form the CMOS transistor. Accordingly, an area occupied by the gate driver 300 and a power consumption may be reduced. In addition, the gate driver 300 may boost a voltage of an internal node (e.g., the first node N1 and the second control node NQ2) using a capacitor (e.g., the first capacitor C1 and the second capacitor C2) to lower the voltage of the internal node below the low gate voltage VGL, and accordingly the gate driver 300 may stably output the gate signal GS. That is, a reliability of the gate driver 300 may increase. In addition, the voltage of the control node NQ1, NQ2 may be toggled. Therefore, a stress applied to the seventh transistor T7 may be reduced, and a deterioration of the seventh transistor T7 may be reduced.

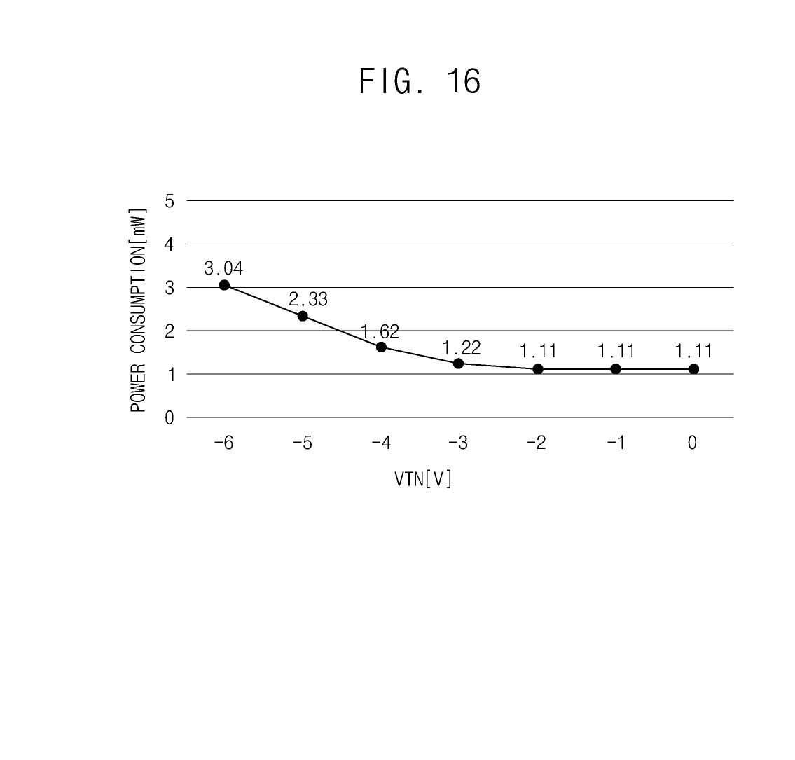

FIG. 16 is a graph showing a power consumption of a gate driver 200 of FIG. 4.

Referring to FIG. 16, a gate driver 200 of FIG. 3 may include NMOS transistors. For example, the NMOS transistors may include a third transistor T3, a fifth transistor T5, and a seventh transistor T7. The NMOS transistors may deteriorate with use, and a threshold voltage VTN of each of the NMOS transistors may decrease.

For example, when the threshold voltage VTN of the NMOS transistor is 0 V, the power consumption of the gate driver 200 may be 1.11 mW. For example, when the threshold voltage VTN of the NMOS transistor is -1 V, the power consumption of the gate driver 200 may be 1.11 mW. For example, when the threshold voltage VTN of the NMOS transistor is -2 V, the power consumption of the gate driver 200 may be 1.11 mW. For example, when the threshold voltage VTN of the NMOS transistor is -3 V, the power consumption of the gate driver 200 may be 1.22 mW. For example, when the threshold voltage VTN of the NMOS transistor is -4 V, the power consumption of the gate driver 200 may be 1.62 mW. For example, when the threshold voltage VTN of the NMOS transistor is -5 V, the power consumption of the gate driver 200 may be 2.33 mW. For example, when the threshold voltage VTN of the NMOS transistor is -6 V, the power consumption of the gate driver 200 may be 3.04 mW.

Generally, when the threshold voltage VTN of the NMOS transistor decreases, a leakage current may occur in the NMOS transistors, resulting in increased power consumption. However, in the gate driver 200, a voltage of a first node N1 is boosted by a first capacitor C1 and lowered below the low gate voltage VGL, such that the third transistor T3 may be sufficiently turned off, and a voltage of the second control node NQ2 is boosted by a second capacitor C2 and lowered below the low gate voltage VGL, such that the seventh transistor T7 may be sufficiently turned off. Therefore, the leakage current may be prevented. Thus, the boosting operation of the first capacitor C1, and the boosting operation of the second capacitor C2 can suppress the increase in power consumption. For a non-limiting example, referring to FIG. 16, a comparison of a case where the threshold voltage VTN of the NMOS transistor is 0 V with a case where the threshold voltage VTN of the NMOS transistor is -3 V may be made. The power consumption of the gate driver 200 is 1.11 mW when the threshold voltage VTN is 0 V, and the power consumption of the gate driver 200 is 1.22 mW when the threshold voltage VTN is -3 V. Thus, the increase in power consumption is about 9.9% (10% or less). As such, the increase in power consumption of the gate driver 200 may be suppressed or reduced by the boosting operations of the first capacitor C1 and the second capacitor C2.

Although the examples and accompanying description above is illustrated for the gate driver with four stages, the plurality of stages may comprise any number of stages. Accordingly, it will be appreciated that the present disclosure is not limited to the exemplary implementations.

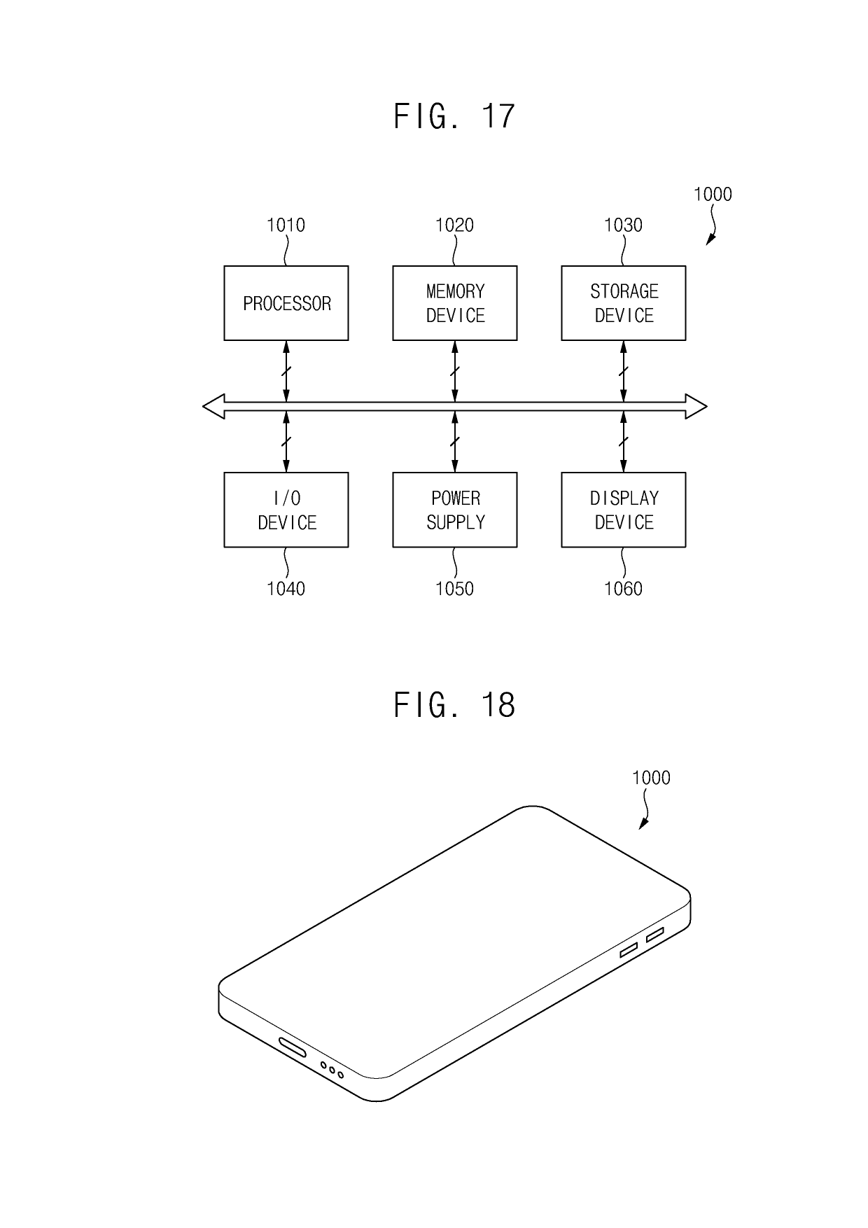

FIG. 17 is a block diagram showing an electronic device 1000. FIG. 18 is a diagram showing an embodiment in which an electronic device 1000 of FIG. 17 is implemented as a smartphone.

Referring to FIGS. 17 and 18, an electronic device 1000 may include a processor 1010, a memory device 1020, a storage device 1030, an input/output I/O device 1040, a power supply 1050, and a display device 1060. The display device 1060 may be the display device 100 of FIG. 1. In addition, the electronic device 1000 may further include a plurality of ports for communicating with a video card, a sound card, a memory card, a universal serial bus USB device, other electronic device, and the like.

In an embodiment, as shown in FIG. 18, the electronic device 1000 may be implemented as a smartphone. However, the electronic device 1000 is not limited thereto. For example, the electronic device 1000 may be implemented as a cellular phone, a video phone, a smart pad, a smart phone, a tablet PC, a car navigation system, a computer monitor, a laptop, a head mounted display HMD device, and the like.

The processor 1010 may perform various computing functions. The processor 1010 may be a micro processor, a central processing unit CPU, an application processor AP, and the like. The processor 1010 may be coupled to other components via an address bus, a control bus, a data bus, and the like. Further, the processor 1010 may be coupled to an extended bus such as a peripheral component interconnection PCI bus.

The memory device 1020 may store data for operations of the electronic device 1000. For example, the memory device 1020 may include at least one nonvolatile memory device such as an erasable programmable read-only memory EPROM device, an electrically erasable programmable read-only memory EEPROM device, a flash memory device, a phase change random access memory PRAM device, a resistance random access memory RRAM device, a nano floating gate memory NFGM device, a polymer random access memory PoRAM device, a magnetic random access memory MRAM device, a ferroelectric random access memory FRAM device, and the like and/or at least one volatile memory device such as a dynamic random access memory DRAM device, a static random access memory SRAM device, a mobile DRAM device, and the like.

The storage device 1030 may include a solid state drive SSD device, a hard disk drive HDD device, a CD-ROM device, and the like.

The I/O device 1040 may include an input device such as a keyboard, a keypad, a mouse device, a touch-pad, a touch-screen, and the like, and an output device such as a printer, a speaker, and the like. In some embodiments, the I/O device 1040 may include the display device 10060.

The power supply 1050 may provide power for operations of the electronic device 1000.

The display device 10060 may be connected to other components through buses or other communication links.

The present disclosure may be implemented for components of any display device and any electronic device including a touch panel. For example, the teachings of the present disclosure may be applied to components of a mobile phone, a smart phone, a tablet computer, a digital television TV, a 3D TV, a personal computer PC, a home appliance, a laptop computer, a personal digital assistant PDA, a portable multimedia player PMP, a digital camera, a music player, a portable game console, a navigation device, etc.

The foregoing is illustrative of aspects of the present disclosure and is not to be construed as limiting thereof. Although a few embodiments of the disclosure have been described, those skilled in the art will readily appreciate that many modifications are possible in the embodiments without materially departing from the novel teachings and advantages of the present disclosure. Accordingly, all such modifications are intended to be included within the scope of the disclosure. In the claims, means-plus-function clauses are intended to cover the structures described herein as performing the recited function and not only structural equivalents but also equivalent structures.

Although the present display device and electronic device have been described with reference to the embodiments shown in the drawings, these are merely exemplary, and those skilled in the art will understand that various modifications and equivalent other embodiments are possible therefrom. Therefore, the disclosed subject matter should not be limited to any single embodiment described herein.

What is claimed is:

1. A gate driver including a plurality of stages and driven based on a high gate voltage and a low gate voltage, wherein each stage of the plurality of stages comprises:
an input circuit configured to provide an input signal to a first node in response to a first clock signal;
a first inverting circuit configured to invert a voltage of the first node and to provide an inverted voltage of the first node to a control node;
a second inverting circuit configured to invert a voltage of a gate output node from which a gate signal is output and to provide an inverted voltage of the gate output node to a second node; and
a third inverting circuit configured to invert a voltage of the control node and to provide an inverted voltage of the control node to the gate output node.

2. The gate driver of claim 1, wherein the input circuit comprises a first transistor including a gate electrode receiving the first clock signal, a first electrode receiving the input signal, and a second electrode connected to the first node.

3. The gate driver of claim 2, wherein the first transistor comprises a PMOS transistor.

4. The gate driver of claim 2, wherein the first inverting circuit comprises:
a second transistor including a gate electrode connected to the first node, a first electrode receiving the high gate voltage, and a second electrode connected to the control node; and
a third transistor including a gate electrode connected to the first node, a first electrode receiving the low gate voltage, and a second electrode connected to the control node.

5. The gate driver of claim 4, wherein the second transistor comprises a PMOS transistor, the third transistor comprises an NMOS transistor, and the second transistor and the third transistor form a CMOS transistor.

6. The gate driver of claim 4, wherein the second inverting circuit further comprises:
a fourth transistor including a gate electrode connected to the gate output node, a first electrode receiving the high gate voltage, and a second electrode connected to the second node; and
a fifth transistor including a gate electrode connected to the gate output node, a first electrode connected to the control node, and a second electrode connected to the second node.

7. The gate driver of claim 6, wherein the fourth transistor comprises a PMOS transistor, the fifth transistor comprises an NMOS transistor, and the fourth transistor and the fifth transistor form a CMOS transistor.

8. The gate driver of claim 6, wherein the third inverting circuit comprises:
a sixth transistor including a gate electrode connected to the control node, a first electrode receiving the high gate voltage, and a second electrode connected to the gate output node; and
a seventh transistor including a gate electrode connected to the control node, a first electrode receiving the low gate voltage, and a second electrode connected to the gate output node.

9. The gate driver of claim 8, wherein the sixth transistor comprises a PMOS transistor, the seventh transistor comprises an NMOS transistor, and the sixth transistor and the seventh transistor form a CMOS transistor.

10. The gate driver of claim 8, wherein the control node comprises a first control node and a second control node, and
each stage of the plurality of stages further comprises an eighth transistor including a gate electrode receiving the low gate voltage, a first electrode connected to the first control node, and a second electrode connected to the second control node.

11. The gate driver of claim 10, wherein each stage of the plurality of stages further comprises a first capacitor including a first electrode connected to the first node and a second electrode connected to the gate output node.

12. The gate driver of claim 11, wherein each stage of the plurality of stages further comprises a second capacitor including a first electrode connected to the second node and a second electrode connected to the control node.

13. The gate driver of claim 2, wherein the first inverting circuit comprises:
a second transistor including a gate electrode connected to the first node, a first electrode receiving a second clock signal, and a second electrode connected to the control node; and
a third transistor including a gate electrode connected to the first node, a first electrode receiving the low gate voltage, and a second electrode connected to the control node.

14. The gate driver of claim 13, wherein the second inverting circuit comprises:
a fourth transistor including a gate electrode connected to the gate output node, a first electrode receiving the second clock signal, and a second electrode connected to the second node; and
a fifth transistor including a gate electrode connected to the gate output node, a first electrode connected to the control node, and a second electrode connected to the second node.

15. The gate driver of claim 14, wherein the third inverting circuit comprises:
a sixth transistor including a gate electrode, a first electrode receiving the high gate voltage, and a second electrode connected to the gate output node; and
a seventh transistor including a gate electrode connected to the control node, a first electrode receiving the low gate voltage, and a second electrode connected to the gate output node.

16. The gate driver of claim 15, wherein the control node comprises a first control node and a second control node, and
each stage of the plurality of stages further comprises an eighth transistor including a gate electrode receiving the low gate voltage, a first electrode connected to the first control node, and a second electrode connected to the second control node.

17. The gate driver of claim 16, wherein each stage of the plurality of stages further comprises:
a first capacitor including a first electrode connected to the first node and a second electrode connected to the gate output node; and
a second capacitor including a first electrode connected to the second node and a second electrode connected to the control node.

18. The gate driver of claim 17, wherein each stage of the plurality of stages further comprises a ninth transistor including a gate electrode receiving the first clock signal, a first electrode connected to the control node, and a second electrode connected to the gate electrode of the sixth transistor.

19. A display device comprising:
a display panel including a plurality of pixels; and
a gate driver configured to provide a gate signal to the plurality of pixels and driven based on a high gate voltage and a low gate voltage,
wherein the gate driver comprises a plurality of stages, and
wherein each stage of the plurality of stages comprises:
an input circuit configured to provide an input signal to a first node in response to a first clock signal;
a first inverting circuit configured to invert a voltage of the first node and to provide an inverted voltage of the first node to a control node;
a second inverting circuit configured to invert a voltage of a gate output node from which the gate signal is output and to provide an inverted voltage of the gate output node to a second node; and
a third inverting circuit configured to invert a voltage of the control node and to provide an inverted voltage of the control node to the gate output node.

20. An electronic device comprising:
a display panel including a plurality of pixels;
a gate driver configured to provide a gate signal to the plurality of pixels and driven based on a high gate voltage and a low gate voltage; and
a power supply configured to provide the high gate voltage and the low gate voltage to the gate driver,
wherein the gate driver comprises a plurality of stages, and
wherein each stage of the plurality of stages comprises:
an input circuit configured to provide an input signal to a first node in response to a first clock signal;
a first inverting circuit configured to invert a voltage of the first node and to provide an inverted voltage of the first node to a control node;
a second inverting circuit configured to invert a voltage of a gate output node from which the gate signal is output and to provide an inverted voltage of the gate output node to a second node; and
a third inverting circuit configured to invert a voltage of the control node and to provide an inverted voltage of the control node to the gate output node.
